(19) United States
(12) Patent Application Publication
(10) Pub. No.: US 2024/0170463 A1
(43) Pub. Date: May 23, 2024

(54) ELECTRONIC DEVICE

(71) Applicant: Renesas Electronics Corporation, Tokyo (JP)

(72) Inventors: Takayuki IGARASHI, Tokyo (JP); Yasutaka NAKASHIBA, Tokyo (JP)

(21) Appl. No.: 18/511,547

(22) Filed: Nov. 16, 2023

(30) Foreign Application Priority Data
Nov. 17, 2022 (JP) 2022-184179

(51) Int. Cl. H01L 25/10; H01L 23/522; H01L 25/065; H01L 25/18

(52) U.S. Cl. CPC H01L 25/105; H01L 23/5227; H01L 25/0655; H01L 25/18; H01L 24/48; H01L 2224/48091; H01L 2224/48137

(57) ABSTRACT

A second distance between a second lower inductor and a second upper inductor, which are components of a second transformer is smaller than a first distance between a first lower inductor and a first upper inductor which are components of a first transformer.

### CROSS-REFERENCE TO RELATED APPLICATIONS

The disclosure of Japanese Patent Application No. 2022-184179 filed on Nov. 17, 2022, including the specification, drawings and abstract is incorporated herein by reference in its entirety.

### BACKGROUND

The present disclosure relates to an electronic device and, for example, to a technique applicable to an electronic device configured to control inverters.

There is a disclosed technique listed below.

[Patent Document 1] Japanese Unexamined Patent Application Publication No. 2011-82212

Patent Document 1 discloses a technique capable of increasing cross-sectional areas of coils without preventing miniaturization in order to reduce a series resistance which occupies most of the parasitic resistance components of the coils configuring the transformer.

### SUMMARY

For example, a control circuit that controls an inverter that drives a load circuit, such as a motor, requires non-contact signal transmission between different potentials. In this regard, photocouplers are commonly used to enable non-contact signal transmission between different potentials.

However, in recent years, with the expansion of electric vehicles, a transformer (digital isolator) using a pair of inductors coupled inductively and a capacitor have attracted attention as a component capable of non-contact signal transmission between different potentials. That is, attention has been focused on transformers and capacitors that can be incorporated in semiconductor chips. Therefore, an amount of production of transformers and capacitors is increasing.

For this reason, in order to gain a competitive advantage with other companies, it is important not only to improve the performance of transformers and capacitors but also to reduce costs. Therefore, a technique for reducing the cost of the transformer and the capacitor is desired.

According to one embodiment, an electronic device includes a first semiconductor device including a first semiconductor chip and a second semiconductor device including a second semiconductor chip. Here, the first semiconductor chip includes a first isolator performing non-contact communication between a first potential and a second potential, while the second semiconductor chip includes a second isolator performing non-contact communication between a third potential and a fourth potential. In this case, a difference between the first potential and the second potential is greater than a difference between the third potential and the fourth potential, the first isolator is configured by a first transformer or a first capacitor, and the second isolator is configured by a second transformer or a second capacitor.

The first transformer includes a first lower inductor, a first upper inductor, and a first insulating layer interposed between the first lower inductor and the first upper inductor. On the other hand, the second transformer includes a second lower inductor, a second upper inductor, and a second insulating layer interposed between the second lower inductor and the second upper inductor. A second distance between the second lower inductor and the second upper inductor is smaller than a first distance between the first lower inductor and the first upper inductor.

The first capacitor includes a first lower electrode, a first upper electrode, and a first capacitive insulating layer interposed between the first lower electrode and the first upper electrode. On the other hand, the second capacitor includes a second lower electrode, a second upper electrode, and a second capacitive insulating layer interposed between the second lower electrode and the second upper electrode. A second capacitance distance between the second lower electrode and the second upper electrode is smaller than a first capacitance distance between the first lower electrode and the first upper electrode.

One embodiment can reduce the cost of the electronic device.

### BRIEF DESCRIPTION OF THE DRAWINGS

FIG. 1 is a circuit diagram showing a configuration of a circuit including an inverter and a three-phase induction motor.

FIG. 2 is a diagram showing a configuration of a gate control circuit.

FIG. 3 is a diagram showing a configuration of an electronic device according to a first embodiment.

FIG. 4 is a diagram showing a configuration of a first semiconductor device having a two-chip configuration.

FIG. 5 is a diagram showing a configuration of a second semiconductor device having a two-chip configuration.

FIG. 6 is a cross-sectional view showing the configuration of the first semiconductor device.

FIG. 7 is a cross-sectional view showing the configuration of the second semiconductor device.

FIG. 8A is a schematic diagram showing a configuration of a first upper inductor that is a component of a first transformer formed in a high-side unit.

FIG. 8B is a schematic diagram showing a configuration of a second upper inductor that is a component of a second transformer formed in a low-side unit.

FIG. 9 is a diagram showing a first semiconductor device of a three-chip configuration.

FIG. 10 is a diagram showing a second semiconductor device of a three-chip configuration.

FIG. 11 is a cross-sectional view showing a configuration of a first semiconductor device in a second embodiment.

FIG. 12 is a cross-sectional view showing a configuration of a second semiconductor device in a second embodiment.

### DETAILED DESCRIPTION

In all the drawings for explaining the embodiments, the same members are denoted by the same reference numerals in principle, and repetitive descriptions thereof are omitted. Note that even plan view may be hatched for the sake of clarity.

The inverter is, for example, a circuit for driving a motor formed in an electric vehicle, a hybrid electric vehicle, a railway vehicle, or an industrial device. The inverter is commercialized as a power module, for example. The inverter is configured to be controlled by a control circuit. The control circuit for controlling the inverters is commercialized, for example, as an electronic device.

### Configuration Example of Three-Phase Inverter

In the following, a three-phase inverter will be described as an example.

The power module is used, for example, in a drive circuit of a three-phase induction motor used in an air conditioner or the like. Specifically, the drive circuit includes an inverter. The inverter includes a function of converting DC power into AC power.

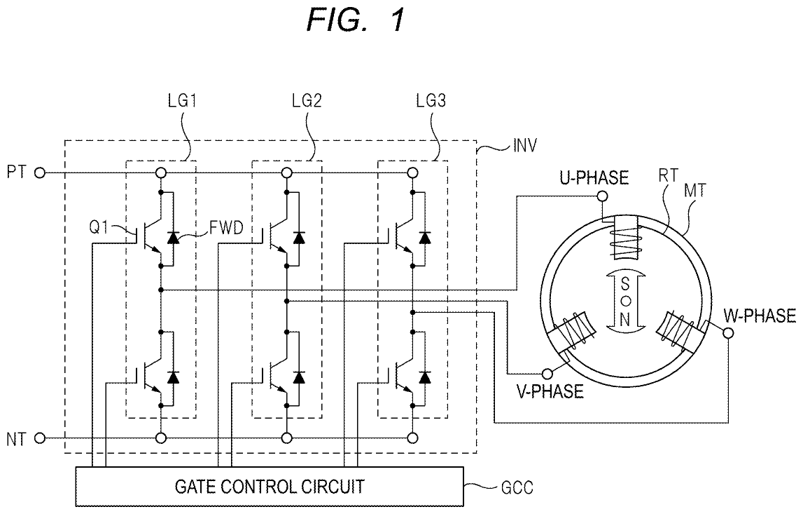

FIG. 1 is a circuit diagram showing a configuration of a motor circuit including an inverter and a three-phase induction motor. In FIG. 1, the motor circuit includes a three-phase induction motor MT and an inverter INV. The three-phase induction motor MT is configured to be driven by three-phase voltages including different phases. Specifically, in the three-phase induction motor MT, a rotating magnetic field is generated around a rotor RT which is a conductor by using a three-phase alternating current called a U-phase, a V-phase, and a W-phase whose phases are shifted by 120 degrees. Here, the magnetic field rotates around the rotor RT. This means that the magnetic flux across the rotor RT, which is a conductor, changes. Consequently, electromagnetic induction occurs in the rotor RT, which is a conductor, and an induced current flows in the rotor RT. The fact that an induced current flows in the rotation magnetic field means that a force is applied to the rotor RT according to Fleming's left-hand law. This force causes the rotor RT to rotate.

As described above, in the three-phase induction motor MT, the rotor RT can be rotated by using the three-phase alternating current. That is, the three-phase induction motor MT requires three-phase alternating current. Therefore, in the motor circuit, three-phase alternating current is supplied to the three-phase induction motor by using the inverter INV that generates alternating current from direct current.

An exemplary configuration of the inverter INV will be described below.

As shown in FIG. 1, for example, the inverter INV is provided with a switching device Q1 and a diode FWD corresponding to three phases. That is, in the inverter INV, for example, the switching device Q1 and the diode FWD as shown in FIG. 1 are connected in anti-parallel, thereby realizing the components of the inverter INV.

For example, in FIG. 1, each of the upper arm and the lower arm of a first leg LG1, the upper arm and the lower arm of a second leg LG2, and the upper arm and the lower arm of a third leg LG3 is configured by a component in which the switching device Q1 and the diode FWD are connected in anti-parallel.

In other words, in the inverter INV, the switching device Q1 and the diode FWD are connected in anti-parallel between a positive potential terminal PT and each phase (U-phase, V-phase, and W-phase) of the three-phase induction motor MT. The switching device Q1 and the diode FWD are also connected in anti-parallel between each phase of the three-phase induction motor MT and a negative potential terminal NT (or the ground terminal). That is, two switching devices Q1 and two diodes FWD are formed for each single phase. In three phases, six switching devices Q1 and six diodes FWD are formed.

A gate control circuit GCC is connected to the gate electrode of the individual switching device Q1. The switching operation of the switching device Q1 is controlled by the gate control circuit GCC. By the gate control circuit GCC controlling the switching operation of the switching device Q1, the DC power is converted into three-phase AC power. This three-phase AC power is supplied to the three-phase induction motor MT.

### Types of Switching Device

Examples of the switching device Q1 used in the inverter INV include a power MOSFET and an IGBT (Insulated Gate Bipolar Transistor).

### Configuration of Gate Control Circuit

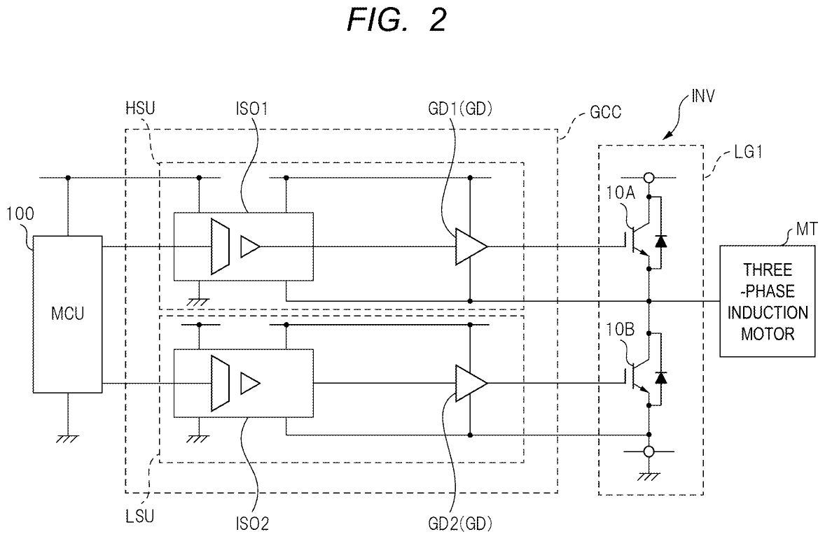

FIG. 2 is a diagram for explaining the configuration of the gate control circuit GCC.

In FIG. 2, the first leg LG1 configuring a part of the inverter INV electrically connected to the three-phase induction motor MT is shown. The first leg LG1 includes, for example, a high-side IGBT (Insulated Gate Bipolar Transistor) 10A and a low-side IGBT 10B. As shown in FIG. 1, the inverter INV includes the first leg LG1, the second leg LG2, and the third leg LG3. Hereinafter, the configuration of the gate control circuit GCC will be described with attention to the first leg LG1.

The inverter INV is electrically connected to the gate control circuit GCC. The gate control circuit GCC is electrically connected to an MCU (Micro Controller Unit) 100.

Here, the gate control circuit GCC is configured to control the switching device configuring the inverter INV based on a command (control signal) from the MCU 100. For example, the gate control circuit GCC is configured to perform on/off control of the high-side IGBT 10A configuring the inverter INV and on/off control of the low-side IGBT 10B. Thus, the three-phase induction motor MT is controlled.

As shown in FIG. 2, the gate control circuit GCC includes a high-side unit HSU and a low-side unit LSU. The high-side unit HSU includes a function of controlling the switching operation of the high-side IGBT 10A. Specifically, the high-side unit HSU includes a high-side gate driver GD1 electrically connected to the gate electrode of the high-side IGBT 10A and the high-side isolator ISO1 electrically connected to the high-side gate driver GD1. The high-side isolator ISO1 is electrically connected to the MCU 100.

On the other hand, the low-side unit LSU includes a function of controlling the switching operation of the low-side IGBT 10B. Specifically, the low-side unit LSU includes a low-side gate driver GD2 electrically connected to the gate electrode the low-side IGBT 10B, and the low-side isolator ISO2 of electrically connected to the low-side gate driver GD2. The low-side isolator ISO2 is electrically connected to the MCU 100.

Here, the MCU 100 and a gate driver GD have different reference potentials. That is, in the MCU 100, the reference potential is fixed to the ground potential, while the gate driver GD is electrically connected to the inverter INV as shown in FIG. 2.

In the inverter INV, the high-side gate driver GD1 performs the on/off control of the high-side IGBT 10A, and the low-side gate driver GD2 performs the on/off control of the low-side IGBT 10B. Thus, the inverter INV controls the three-phase induction motor MT.

Specifically, the high-side gate driver GD1 performs the on/off control of the high-side IGBT 10A by controlling the potential applied to the gate electrode of the high-side IGBT 10A. Similarly, the low-side gate driver GD2 performs the on/off control of the low-side IGBT 10B by controlling the potential applied to the gate electrode of the low-side IGBT 10B.

Here, for example, the on-control of the low-side IGBT 10B is realized by applying “emitter potential (0 V)+threshold voltage (15 V)” to the gate electrode with reference to the emitter potential (0 V) of the low-side IGBT 10B connected to the ground potential.

On the other hand, for example, the off-control of the low-side IGBT 10B is realized by applying an “emitter potential (0 V)” to the gate electrode with reference to the emitter potential (0 V) of the low-side IGBT 10B connected to the ground potential.

Therefore, the on/off control of the low-side IGBT 10B is performed according to whether or not a threshold voltage (15 V) is applied to the gate electrode with 0 V as a reference potential.

On the other hand, for example, the on-control of the high-side IGBT 10A is also performed according to whether or not “reference potential+threshold voltage (15 V)” is applied to the gate electrode with respect to the reference potential using the emitter potential of the high-side IGBT 10A as a reference potential.

However, the emitter potential of the high-side IGBT 10A is not fixed to the ground potential as is the emitter potential of the low-side IGBT 10B. That is, in the inverter INV, the high-side IGBT 10A and the low-side IGBT 10B are connected in series between the power supply potential and the ground potential. In the inverter INV, when the high-side IGBT 10A is turned on, the low-side IGBT 10B is turned off, and when the high-side IGBT 10A is turned off, the low-side IGBT 10B is turned on.

Therefore, when the high-side IGBT 10A is turned off, since the low-side IGBT 10B is turned on, the emitter potential of the high-side IGBT 10A becomes a ground potential due to the on low-side IGBT 10B.

On the other hand, when the high-side IGBT 10A is turned on, since the low-side IGBT 10B is turned off, the emitter potential of the high-side IGBT 10A becomes an IGBT bus voltage. At this time, the on/off control of the high-side IGBT 10A is performed according to whether or not “reference potential+threshold voltage (15 V)” is applied to the gate electrode with the emitter potential of the high-side IGBT 10A as a reference potential.

As described above, the emitter potential of the high-side IGBT 10A varies depending on whether the high-side IGBT 10A is turned on or turned off. That is, the emitter potential of the high-side IGBT 10A varies from the ground potential (0 V) to the power supply potential (for example, 800 V). Therefore, in order to turn on the high-side IGBT 10A, an “IGBT bus voltage (800 V)+threshold voltage (15 V)” needs to be applied to the gate electrode with the emitter potential of the high-side IGBT 10A as a reference potential.

Therefore, the high-side gate driver GD1 that performs on/off control of the high-side IGBT 10A needs to detect the emitter potential of the high-side IGBT 10A. Therefore, the high-side gate driver GD1 is configured to receive the emitter potential of the high-side IGBT 10A. Consequently, the reference potential of 800 V is inputted to the high-side gate driver GD1. Then, the high-side gate driver GD1 controls the high-side IGBT 10A to be turned on by applying the threshold voltage (15 V) to the gate electrode of the high-side IGBT 10A with respect to the reference potential of 800 V. Therefore, a high potential of the order of 800 V is applied to the high-side gate driver GD1.

As described above, the circuit controlling the inverter INV includes the MCU 100 handling a low potential (several V) and the high-side gate driver GD1 handling a high potential (several hundred V). Therefore, the signal transmission between the MCU 100 and the high-side gate driver GD1 requires to be performed between the different potential circuits. Since the signal transmission is performed between the MCU 100 and the high-side gate driver GD1 with the high-side isolator ISO1 interposed therebetween, the signal transmission can be performed between the different potential circuits. The high-side isolator ISO1 includes a function of transmitting a signal between different potential circuits, and also includes a function of, for example, (1) level-shifting between a low potential (several V) and a high potential (several hundred V), and (2) isolating a power supply/GND between the noise-sensitive MCU 100 (low-voltage domain) and the noisy high-side gate driver GD1 (high-voltage domain).

On the other hand, in the low-side gate driver GD2, as described above, a high potential of several hundred V is not handled as in the high-side gate driver GD1, and a potential of several tens V is handled. However, even in the low-side gate driver GD2, a higher potential than the MCU 100 that handles the low potential (several V) is handled. Therefore, the signal transmission between the MCU 100 and the low-side gate driver GD2 requires to be performed between the different potential circuits. Since the signal transmission is performed between the MCU 100 and the low-side gate driver GD2 with the low-side isolator ISO2 interposed therebetween, the signal transmission can be performed between the different potential circuits. The low-side isolator ISO2 includes a function of transmitting a signal between different potential circuits, and also includes a function of, for example, (1) level-shifting between a low potential (several V) and a high potential (several tens V), and (2) isolating a power supply/GND between the noise-sensitive MCU 100 (low-voltage domain) and the noisy low-side gate driver GD2 (high-voltage domain).

The gate control circuit GCC is configured as described above.

### Basic Concept in Present Embodiment

Next, the basic concept in the present embodiment is explained.

The high-side isolator ISO1 formed between the MCU 100 handling a low potential (several V) and the high-side gate driver GD1 handling a high potential (several hundred V) requires a high breakdown voltage. On the other hand, the low-side isolator ISO2 formed between the MCU 100 handling the low potential (several V) and the low-side gate driver GD2 handling the potential (several tens V) does not require a higher breakdown voltage than the high-side isolator ISO1.

In this regard, the structure of the high-side isolator ISO1 and the structure of the low-side isolator ISO2 are common. In this case, a common isolator is designed so that the high-side isolator ISO1 can ensure an enough high breakdown voltage.

Then, the low-side isolator ISO2 ensures more breakdown voltage than necessary. That is, if the structure of the high-side isolator ISO1 and the structure of the low-side isolator ISO2 are common, the performance of the low-side isolator ISO2 becomes excessive. In other words, more performance than necessary is provided to the low-side isolator ISO2. That is, if the structure of the high-side isolator ISO1 and the structure of the low-side isolator ISO2 are common, the structure of the isolator is necessarily designed to meet the demanding specifications. Consequently, a more performance than necessary is added in the low-side isolator ISO2 with a moderate demand.

This means that the manufacturing of the low-side isolator ISO2 with moderate demands requires excess manufacturing cost. Therefore, there is room for improvement to commonize the structure of the high-side isolator ISO1 and the structure of the low-side isolator ISO2 of which required breakdown voltages are greatly different from the viewpoint of reducing the manufacturing cost of the isolator.

Therefore, the basic concept of the present embodiment is based on that the structure of the high-side isolator ISO1 and the structure of the low-side isolator ISO2 are different from each other. The basic concept is to adopt a structure capable of exhibiting enough performance to satisfy the breakdown voltage required for each of them for each of the high-side isolator ISO1 and the low-side isolator ISO2.

According to this basic concept, in the low-side isolator ISO2 with a moderate demand, a structure including enough performance to satisfy the breakdown voltage required for the low-side isolator ISO2 is adopted without adopting a structure designed in accordance with the specification of the high-side isolator ISO1 with strict demand. Therefore, the basic concept can prevent excessive performance from being added to the low-side isolator ISO2 with a moderate demand, and can reduce the manufacturing cost of the low-side isolator ISO2.

In the following, an embodiment embodying the basic concept will be described. In particular, in the embodiment, an example of configuring an isolator from a transformer utilizing a pair of inductors induced coupled (magnetically coupled) will be described. A modified example describes an exemplary configuration of an isolator from a capacitor using a pair of capacitively coupled electrodes.

### First Embodiment

### Configuration of Electronic Device

For example, the gate control circuit GCC shown in FIG. 2 is embodied as an electronic device EA. That is, the electronic device EA is configured to control the inverters.

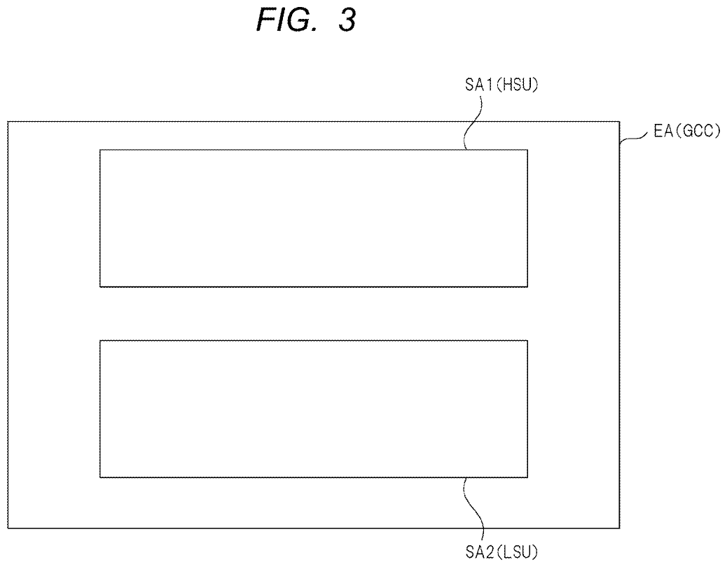

FIG. 3 is a diagram showing configuration of the electronic device EA according to the first embodiment.

In FIG. 3, the electronic device EA includes a first semiconductor device SA1 and a second semiconductor device SA2. The first semiconductor device SA1 is formed of, for example, a packaging structure. The first semiconductor device SA1 includes the components of the high-side unit HSU shown in FIG. 2. On the other hand, the second semiconductor device SA2 is also configured by, for example, a packaging structure. The second semiconductor device SA2 includes the components of the low-side unit LSU shown in FIG. 2. In this way, the electronic device EA in the first embodiment is configured.

### Functional Block Configuration of First Semiconductor Device

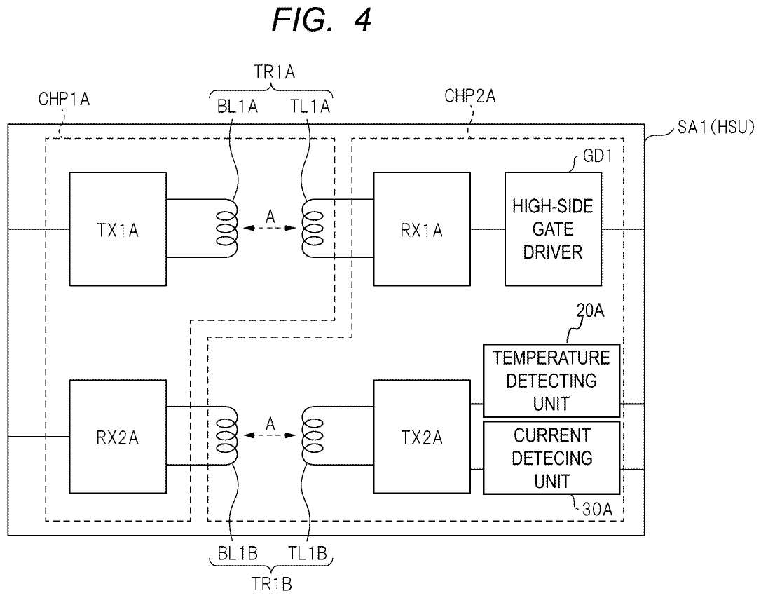

FIG. 4 is a block diagram showing a configuration of the first semiconductor device SA1 including the high-side unit HSU of the gate control circuit GCC.

As shown in FIG. 4, the first semiconductor device SA1 includes a transmitting circuit TX1A, a transformer TR1A, a receiving circuit RX1A, and the high-side gate driver GD1.

Here, the transmitting circuit TX1A is electrically connected to the MCU 100 shown in FIG. 2. Each of the transmitting circuit TX1A and the receiving circuit RX1A is electrically connected to the transformer TR1A. Specifically, the transformer TR1A includes a lower inductor BL1A and an upper inductor TL1A. The transmitting circuit TX1A is electrically connected to the lower inductor BL1A. The receiving circuit RX1A is electrically connected to the upper inductor TL1A. Further, the receiving circuit RX1A is electrically connected to the high-side gate driver GD1. The high-side gate driver GD1 is electrically connected to the gate electrode of the high-side IGBT 10A shown in FIG. 2.

The transmitting circuit TX1A and the receiving circuit RX1A transmitting a control signal outputted from the MCU 100 (see FIG. 2) to the high-side gate driver GD1.

Between the transmitting circuit TX1A and the receiving circuit RX1A, the transformer TR1A configured by the lower inductor BL1A and the upper inductor TL1A inductively coupled to each other is interposed. Thus, the control signal can be transmitted from the transmitting circuit TX1A to the receiving circuit RX1A via the transformer TR1A. Consequently, the high-side gate driver GD1 can receive the control signal outputted from the MCU 100 (see FIG. 2) via the transformer TR1A.

Thus, the transformer TR1A electrically isolated using inductive coupling can transmit the control signal from the MCU 100 (refer to FIG. 2) to the high-side gate driver GD1 while suppressing the transfer of electrical noises from the MCU 100 (see FIG. 2) to the high-side gate driver GD1. Therefore, it is possible to suppress malfunction of the high-side gate driver GD1 caused by superimposition of electric noises on the control signal. Thus, the operation reliability of the first semiconductor device SA1 can be improved.

The lower inductor BL1A and the upper inductor TL1A configuring the transformer TR1A each function as an inductor. The transformer TR1A functions as a magnetic coupling device including the lower inductor BL1A and the upper inductor TL1A inductively coupled to each other. As described above, the transformer TR1A includes the lower inductor BL1A and the upper inductor TL1A. The lower inductor BL1A and the upper inductor TL1A are not connected to each other via conductors and are magnetically coupled to each other.

Therefore, when a current flows in the lower inductor BL1A, an induced electromotive force is generated in the upper inductor TL1A in accordance with a change in the current, and an induced current flows in the upper inductor TL1A. Here, the lower inductor BL1A is a primary coil, and the upper inductor TL1A is a secondary coil. As described above, the transformer TR1A utilizes electromagnetic induction phenomena occurring between the lower inductor BL1A and the upper inductor TL1A. That is, the receiving circuit RX1A detects the induced current generated in the upper inductor TL1A of the transformer TR1A as a result that the signal is transmitted from the transmitting circuit TX1A to the lower inductor BL1A of the transformer TR1A and a current flows. Thus, the receiving circuit RX1A can receive a signal corresponding to the control signal outputted from the transmitting circuit TX1A.

As described above, the control signal is transmitted from the MCU 100 (see FIG. 2) to the high-side gate driver GD1 through the path from the transmitting circuit TX1A to the receiving circuit RX1A via the transformer TR1A. That is, by the receiving circuit RX1A receiving the control signal transmitted by the transmitting circuit TX1A, the control signal can be transmitted from the MCU 100 (see FIG. 2) to the high-side gate driver GD1. Accordingly, the high-side gate driver GD1 can perform on/off control of the high-side IGBT 10A, which is a component of the inverter INV (refer to FIG. 2) for operating the three-phase induction motor MT (see FIG. 2), in response to the control signal transmitted from the MCU 100 (see FIG. 2).

Subsequently, the first semiconductor device SA1 includes a temperature detecting unit 20A, a current detecting unit 30A, a transmitting circuit TX2A, a transformer TR1B, and a receiving circuit RX2A.

Here, the receiving circuit RX2A is electrically connected to the MCU 100 shown in FIG. 2. Each of the receiving circuit RX2A and the transmitting circuit TX2A is electrically connected to the transformer TR1B. Specifically, the transformer TR1B includes a lower inductor BL1B and an upper inductor TL1B. The receiving circuit RX2A is electrically connected to the lower inductor BL1B. On the other hand, the transmitting circuit TX2A is electrically connected to the upper inductor TL1B. Further, the transmitting circuit TX2A is electrically connected to the temperature detecting unit 20A and the current detecting unit 30A.

The temperature detecting unit 20A is electrically connected to the temperature detecting diode built in the inverter INV shown in FIG. 2. That is, the temperature detecting diode is also formed with the high-side IGBT 10A in the IGBT chip on which the high-side IGBT 10A shown in FIG. 2 is formed. The temperature detecting unit 20A is electrically connected to the temperature detecting diode. On the other hand, the current detecting unit 30A is electrically connected to a sense transistor that detects a current flowing through the high-side IGBT 10A (main transistor). That is, the sense transistor is also formed together with the high-side IGBT 10A, which is a main transistor, in the IGBT chip on which the high-side IGBT 10A is formed. The current detecting unit 30A is electrically connected to the sense transistor.

The temperature detecting unit 20A is configured to detect a forward voltage drop of the temperature detecting diode formed in the IGBT chip. A temperature detection signal indicating the forward voltage drop is outputted from the temperature detecting unit 20A to the transmitting circuit TX2A.

The current detecting unit 30A is configured to detect a sense current flowing through the sense transistor formed in the IGBT chip. The current detecting unit 30A outputs a current detection signal indicating a sense current to the transmitting circuit TX2A.

The transmitting circuit TX2A and the receiving circuit RX2A transmit the temperature detection signal outputted from the temperature detecting unit 20A and the current detection signal outputted from the current detecting unit 30A to the MCU 100 (refer to FIG. 2).

Between the transmitting circuit TX2A and the receiving circuit RX2A, the transformer TR1B configured by the lower inductor BL1B and the upper inductor TL1B inductively coupled to each other is interposed. Thus, the temperature detection signal and the current detection signal can be transmitted from the transmitting circuit TX2A to the receiving circuit RX2A via the transformer TR1B. Consequently, the MCU 100 (see FIG. 2) can receive the temperature detection signal outputted from the temperature detecting unit 20A and the current detection signal outputted from the current detecting unit 30A via the transformer TR1B.

As described above, by the transformer TR1B electrically isolated by using inductive coupling, the temperature detection signal and the current detection signal can be transmitted from the temperature detecting unit 20A and the current detecting unit 30A to the MCU 100 (refer to FIG. 2) while suppressing the transmission of electric noises from the temperature detecting unit 20A and the current detecting unit 30A to the MCU 100 (see FIG. 2). Therefore, a malfunction of the MCU 100 (see FIG. 2) caused by the superimposition of the electric noises on the temperature detection signal and the current detection signal can be suppressed. Thus, the operation reliability of the first semiconductor device SA1 can be improved.

The lower inductor BL1B and the upper inductor TL1B configuring the transformer TR1B each function as an inductor. The transformer TR1B functions as a magnetic coupling device including the lower inductor BL1B and the upper inductor TL1B inductively coupled to each other. As described above, the transformer TR1B includes the lower inductor BL1B and the upper inductor TL1B. The lower inductor BL1B and the upper inductor TL1B are not connected to each other via conductors and are magnetically coupled to each other.

Therefore, when a current flows in the upper inductor TL1B, an induced electromotive force is generated in the lower inductor BL1B in accordance with a change in the current, and an induced current flows in the lower inductor BL1B. The upper inductor TL1B is a primary coil, and the lower inductor BL1B is a secondary coil. As described above, the transformer TR1B utilizes electromagnetic induction phenomena occurring between the lower inductor BL1B and the upper inductor TL1B. That is, the receiving circuit RX2A detects the induced current generated in the lower inductor BL1B of the transformer TR1B as a result that the signal is transmitted from the transmitting circuit TX2A to the upper inductor TL1B of the transformer TR1B and a current flows. Thus, the receiving circuit RX2A can receive the temperature detection signal and the current detection signal outputted from the transmitting circuit TX2A.

As described above, the temperature detection signal and current detection signal are transmitted from the the temperature detecting unit 20A and the current detecting unit 30A to the MCU 100 (refer to FIG. 2) by the path from the transmitting circuit TX2A to the receiving circuit RX2A via the transformer TR1B. That is, by the receiving circuit RX2A receiving the temperature detection signal and the current detection signal transmitted from the transmitting circuit TX2A, the temperature detection signal and the current detection signal can be transmitted from the temperature detecting unit 20A and the current detecting unit 30A to the MCU 100 (refer to FIG. 2).

Thus, the MCU 100 (see FIG. 2) can detect the temperature of the IGBT chip based on the temperature detection signal indicating the forward voltage drop. Specifically, the forward voltage drop of the temperature detecting diode includes a temperature dependence. Therefore, for example, the MCU 100 (see FIG. 2) can indirectly detect the temperature on the basis of the temperature detection signal indicating the forward voltage drop when a constant current flows through the temperature detection diode. Further, the MCU 100 (see FIG. 2) can detect the main current flowing through the high-side IGBT 10A (main transistor) based on the current detection signal indicating the sense current flowing through the sense transistor and a sense ratio (main current:sense current) acquired in advance.

The first semiconductor device SA1 is configured as described above.

### Two-Chip Configuration

The first semiconductor device SA1 including the high-side unit HSU is, for example, configured by two semiconductor chips. Specifically, as shown in FIG. 4, the transmitting circuit TX1A, the transformer TR1A, and the receiving circuit RX2A are formed in a semiconductor chip CHP1A.

On the other hand, the receiving circuit RX1A, the high-side gate driver GD1, the transmitting circuit TX2A, the transformer TR1B, the temperature detecting unit 20A, and the current detecting unit 30A are formed in a semiconductor chip CHP2A.

In such a two-chip configuration, for example, the transformer TR1A is formed on the same semiconductor chip CHP1A as the transmitting circuit TX1A and the receiving circuit RX2A. Therefore, the transformer TR1A, the transmitting circuit TX1A, and the receiving circuit RX2A can be integrated.

Similarly, the transformer TR1B is formed on the same semiconductor chip CHP2A as the high-side gate driver GD1, the receiving circuit RX1A, the transmitting circuit TX2A, the temperature detecting unit 20A, and the current detecting unit 30A. Therefore, the transformer TR1B, the high-side gate driver GD1, the receiving circuit RX1A, the transmitting circuit TX2A, the temperature detecting unit 20A, and the current detecting unit 30A can be integrated.

Here, for example, the transmitting circuit TX1A and the receiving circuit RX2A are formed in the semiconductor chip CHP1A. Therefore, transistors configuring the transmitting circuit TX1A and the receiving circuit RX2A are formed in the semiconductor chip CHP1A.

Similarly, the high-side gate driver GD1, the receiving circuit RX1A, the transmitting circuit TX2A, the temperature detecting unit 20A, and the current detecting unit 30A are formed in the semiconductor chip CHP2A. Therefore, transistors configuring the high-side gate driver GD1, the receiving circuit RX1A, the transmitting circuit TX2A, the temperature detecting unit 20A, and the current detecting unit 30A are also formed in the semiconductor chip CHP2A. Therefore, the transformer TR1A and the transistors are formed together in the semiconductor chip CHP1A. Similarly, the transformer TR1B and the transistors are formed together in the semiconductor chip CHP2A.

### Functional Block Configuration of Second Semiconductor Device

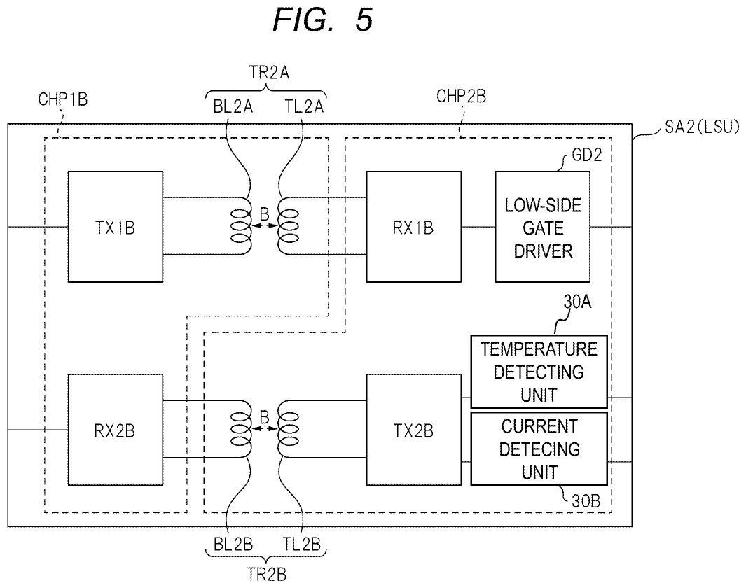

FIG. 5 is a block diagram showing a configuration of the second semiconductor device SA2 including the low-side unit LSU of the gate control circuit GCC.

As shown in FIG. 5, the second semiconductor device SA2 includes a transmitting circuit TX1B, a transformer TR2A, a receiving circuit RX1B, and the low-side gate driver GD2.

Here, the transmitting circuit TX1B is electrically connected to the MCU 100 shown in FIG. 2. Each of the transmitting circuit TX1B and the receiving circuit RX1B is electrically connected to the transformer TR2A. Specifically, the transformer TR2A includes a lower inductor BL2A and an upper inductor TL2A. The transmitting circuit TX1B is electrically connected to the lower inductor BL2A. On the other hand, the receiving circuit RX1B is electrically connected to the upper inductor TL2A. Further, the receiving circuit RX1B is electrically connected to the low-side gate driver GD2. The low-side gate driver GD2 is electrically connected to the gate electrode of the low-side IGBT 10B shown in FIG. 2.

The transmitting circuit TX1B and the receiving circuit RX1B transmit a control signal outputted from the MCU 100 (see FIG. 2) to the low-side gate driver GD2.

Between the transmitting circuit TX1B and the receiving circuit RX1B, the transformer TR2A configured by the lower inductor BL2A and the upper inductor TL2A inductively coupled to each other is interposed. Thus, the control signal can be transmitted from the transmitting circuit TX1B to the receiving circuit RX1B via the transformer TR2A. Consequently, the low-side gate driver GD2 can receive the control signal outputted from the MCU 100 (see FIG. 2) via the transformer TR2A.

As described above, by the transformer TR2A electrically isolated by inductive coupling, the control signal can be transmitted from the MCU 100 (refer to FIG. 2) to the low-side gate driver GD2 while suppressing the transfer of electric noises from the MCU 100 (see FIG. 2) to the low-side gate driver GD2. Therefore, the malfunction of the low-side gate driver GD2 caused by the superimposition of the electric noises on the control signal can be suppressed. Accordingly, the operation reliability of the second semiconductor device SA2 can be improved.

The lower inductor BL2A and the upper inductor TL2A configuring the transformer TR2A each function as an inductor. The transformer TR2A functions as a magnetic coupling device including the lower inductor BL2A and the upper inductor TL2A inductively coupled to each other. As described above, the transformer TR2A includes the lower inductor BL2A and the upper inductor TL2A. The lower inductor BL2A and the upper inductor TL2A are not connected to each other via conductors and are magnetically coupled to each other.

Therefore, when a current flows in the lower inductor BL2A, an induced electromotive force is generated in the upper inductor TL2A in accordance with a change in the current, and an induced current flows in the upper inductor TL2A. Here, the lower inductor BL2A is a primary coil, and the upper inductor TL2A is a secondary coil. As described above, the transformer TR2A utilizes electromagnetic induction phenomena occurring between the lower inductor BL2A and the upper inductor TL2A. That is, the receiving circuit RX1B can receive a signal corresponding to the control signal outputted from the transmitting circuit TX1B by detecting the induced current generated in the upper inductor TL2A of the transformer TR2A as a result that a signal is transmitted from the transmitting circuit TX1B to the lower inductor TR2A of the transformer BL2A and a current flows.

As described above, the control signal is transmitted from the MCU 100 (see FIG. 2) to the low-side gate driver GD2 through the path from the transmitting circuit TX1B to the receiving circuit RX1B via the transformer TR2A. That is, by the receiving circuit RX1B receiving the control signal transmitted by the transmitting circuit TX1B, the control signal can be transmitted from the MCU 100 (see FIG. 2) to the low-side gate driver GD2. Accordingly, the low-side gate driver GD2 can perform on/off control of the low-side IGBT 10B, which is a component of the inverter INV (refer to FIG. 2) for operating the three-phase induction motor MT (see FIG. 2), in response to the control signal transmitted from the MCU 100 (see FIG. 2).

Subsequently, the second semiconductor device SA2 includes a temperature detecting unit 20B, a current detecting unit 30B, a transmitting circuit TX2B, a transformer TR2B, and a receiving circuit RX2B.

Here, the receiving circuit RX2B is electrically connected to the MCU 100 shown in FIG. 2. Each of the receiving circuit RX2B and the transmitting circuit TX2B is electrically connected to the transformer TR2B. Specifically, the transformer TR2B includes a lower inductor BL2B and an upper inductor TL2B. The receiving circuit RX2B is electrically connected to the lower inductor BL2B. On the other hand, the transmitting circuit TX2B is electrically connected to the upper inductor TL2B. Further, the transmitting circuit TX2B is electrically connected to the temperature detecting unit 20B and the current detecting unit 30B.

The temperature detecting unit 20B is electrically connected to the temperature detecting diode built in the inverter INV shown in FIG. 2. That is, the temperature detecting diode is also formed with the low-side IGBT 10B in the IGBT chip on which the low-side IGBT 10B shown in FIG. 2 is formed. The temperature detecting unit 20B is electrically connected to the temperature detecting diode. On the other hand, the current detecting unit 30B is electrically connected to the sense transistor that detects a current flowing through the low-side IGBT 10B (main transistor). That is, the sense transistor is also formed together with the low-side IGBT 10B, which is a main transistor, in the IGBT chip on which the low-side IGBT 10B is formed. The current detecting unit 30B is electrically connected to the sense transistor.

The temperature detecting unit 20B is configured to detect a forward voltage drop of the temperature detecting diode formed in the IGBT chip. A temperature detection signal indicating the forward voltage drop is outputted from the temperature detecting unit 20B to the transmitting circuit TX2B.

The current detecting unit 30B is configured to detect a sense current flowing through the sense transistor formed in the IGBT chip. The current detecting unit 30B outputs a current detection signal indicating a sense current to the transmitting circuit TX2B.

The transmitting circuit TX2B and the receiving circuit RX2B transmit the temperature detection signal outputted from the temperature detecting unit 20B and the current detection signal outputted from the current detecting unit 30B to the MCU 100 (refer to FIG. 2).

Between the transmitting circuit TX2B and the receiving circuit RX2B, the transformer TR2B configured by the lower inductor BL2B and the upper inductor TL2B inductively coupled to each other is interposed. Thus, the temperature detection signal and the current detection signal can be transmitted from the transmitting circuit TX2B to the receiving circuit RX2B via the transformer TR2B. Consequently, the MCU 100 (see FIG. 2) can receive the temperature detection signal outputted from the temperature detecting unit 20B and the current detection signal outputted from the current detecting unit 30B via the transformer TR2B.

As described above, by the transformer TR2B electrically isolated by using inductive coupling, the temperature detection signal and the current detection signal can be transmitted from the temperature detecting unit 20B and the current detecting unit 30B to the MCU 100 (refer to FIG. 2) while suppressing the transmission of electric noises from the temperature detecting unit 20B and the current detecting unit 30B to the MCU 100 (see FIG. 2). Therefore, a malfunction of the MCU 100 (see FIG. 2) caused by the superimposition of the electric noises on the temperature detection signal and the current detection signal can be suppressed. As a result, the operation reliability of the second semiconductor device SA2 can be improved.

The lower inductor BL2B and the upper inductor TL2B configuring the transformer TR2B each function as an inductor. The transformer TR2B functions as a magnetic coupling device including the lower inductor BL2B and the upper inductor TL2B inductively coupled to each other. As described above, the transformer TR2B includes the lower inductor BL2B and the upper inductor TL2B. The lower inductor BL2B and the upper inductor TL2B are not connected by conductors, but are magnetically coupled to each other.

Therefore, when a current flows in the upper inductor TL2B, an induced electromotive force is generated in the lower inductor BL2B in accordance with a change in the current, and an induced current flows in the lower inductor BL2B. Here, the upper inductor TL2B is a primary coil, and the lower inductor BL2B is a secondary coil. As described above, the transformer TR2B utilizes electromagnetic induction phenomena occurring between the lower inductor BL2B and the upper inductor TL2B. That is, the receiving circuit RX2B can receive the temperature detection signal and the current detection signal outputted from the transmitting circuit TR2B by detecting the induced current generated in the lower inductor BL2B of the transformer TR2B as a result that a signal is transmitted from the transmitting circuit TX2B to the upper inductor TR2B of the transformer TL2B and a current flows.

As described above, the temperature detection signal and the current detection signal are transmitted from the temperature detecting unit 20B and the current detecting unit 30B to the MCU 100 (refer to FIG. 2) through the path from the transmitting circuit TX2B to the receiving circuit RX2B via the transformer TR2B. That is, the receiving circuit RX2B receives the temperature detection signal and the current detection signal transmitted by the transmitting circuit TX2B, so that the temperature detection signal and the current detection signal can be transmitted from the temperature detecting unit 20B and the current detecting unit 30B to the MCU 100 (refer to FIG. 2).

Thus, the MCU 100 (see FIG. 2) can detect the temperature of the IGBT chip based on the temperature detection signal indicating the forward voltage drop. Specifically, the forward voltage drop of the temperature detecting diode includes a temperature dependence. Therefore, for example, the MCU 100 (see FIG. 2) can indirectly detect the temperature on the basis of the temperature detection signal indicating the forward voltage drop when a constant current flows through the temperature detection diode. Further, the MCU 100 (see FIG. 2) can detect the main current flowing through the low-side IGBT 10B (main transistor) based on the current detection signal indicating the sense current flowing through the sense transistor and a sense ratio (main current:sense current) acquired in advance.

The second semiconductor device SA2 is configured as described above.

### Two-Chip Configuration

The second semiconductor device SA2 including the low-side unit LSU, for example, is configured by two semiconductor chips. Specifically, as shown in FIG. 5, the transmitting circuit TX1B, the transformer TR2A, and the receiving circuit RX2B are formed in a semiconductor chip CHP1B.

On the other hand, the receiving circuit RX1B, the low-side gate driver GD2, the transmitting circuit TX2B, the transformer TR2B, the temperature detecting unit 20B, and the current detecting unit 30B are formed in a semiconductor chip CHP2B.

In such a two-chip configuration, for example, the transformer TR2A is formed on the same semiconductor chip CHP1B as the transmitting circuit TX1B and the receiving circuit RX2B. Therefore, the transformer TR2A, the transmitting circuit TX1B, and the receiving circuit RX2B can be integrated.

Similarly, the transformer TR2B is formed on the same semiconductor chip CHP2B as the low-side gate driver GD2, the receiving circuit RX1B, the transmitting circuit TX2B, the temperature detecting unit 20B, and the current detecting unit 30B. Therefore, the transformer TR2B, the low-side gate driver GD2, the receiving circuit RX1B, the transmitting circuit TX2B, the temperature detecting unit 20B, and the current detecting unit 30B can be integrated.

Here, for example, the transmitting circuit TX1B and the receiving circuit RX2B are formed in the semiconductor chip CHP1B. Therefore, transistors configuring the transmitting circuit TX1B and the receiving circuit RX2B are formed in the semiconductor chip CHP1B.

Similarly, the low-side gate driver GD2, the receiving circuit RX1B, the transmitting circuit TX2B, the temperature detecting unit 20B, and the current detecting unit 30B are formed in the semiconductor chip CHP2B. Therefore, transistors configuring the low-side gate driver GD2, the receiving circuit RX1B, the transmitting circuit TX2B, the temperature detecting unit 20B, and the current detecting unit 30B are also formed in the semiconductor chip CHP2B. Therefore, in the semiconductor chip CHP1B, the transformer TR2A and the transistors are formed together. Similarly, in the semiconductor chip CHP2B, the transformer TR2B and the transistors are formed together.

### Configuration of First Semiconductor Device

Next, the configuration of the first semiconductor device SA1 will be described.

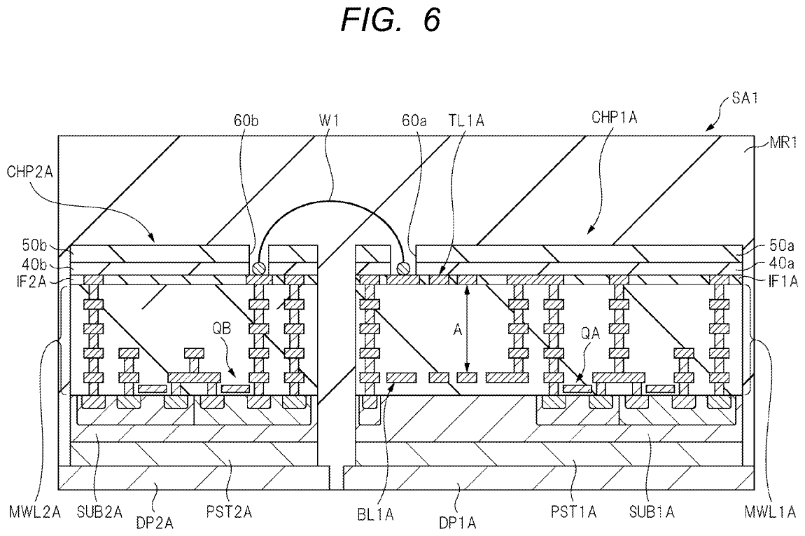

FIG. 6 is a cross-sectional view showing the configuration of the first semiconductor device SA1.

In FIG. 6, the first semiconductor device SA1 includes the semiconductor chip CHP1A and the semiconductor chip CHP2A. That is, the semiconductor device SA1 includes a two-chip configuration. The semiconductor chip CHP1A is mounted, for example, on a die pad DP1A that is a chip mounting portion via a conductive adhesive PST1A. On the other hand, the semiconductor chip CHP2A is mounted, for example, on a die pad DP2A which is a chip mounting portion via a conductive adhesive PST2A.

Here, each of the die pad DP1A and the die pad DP2A is made of, for example, a copper material. Each of the conductive adhesive PST1A and the conductive adhesive PST2A is made of, for example, silver-paste or solder.

The transmitting circuit TX1A, the receiving circuit RX2A, and the transformer TR1A shown in FIG. 4 are formed in the semiconductor chip CHP1A. As shown in FIG. 6, the semiconductor chip CHP1A includes a semiconductor substrate SUB1A and a multilayer wiring layer MWL1A formed on the semiconductor substrate SUB1A. A plurality of transistors QA are formed on the semiconductor substrate SUB1A. The multilayer wiring layer MWL1A is formed over the semiconductor substrate SUB1A on which the plurality of transistors QA are formed. The lowermost layer of the multilayer wiring layer MWL1A is in contact with the semiconductor substrate SUB1A.

In the multilayer wiring layer MWL1A, a plurality of interlayer insulating films and a plurality of wirings are laminated. A wiring is formed in each layer of the multilayer wiring layer MWL1A. The wiring is electrically connected to the transistor QA. The transistor QA and the wiring electrically connected to each other configure the transmitting circuit TX1A and the receiving circuit RX2A.

In addition to the wiring, the multilayer wiring layer MWL1A also includes the lower inductor BL1A which is a component of the transformer TR1A. The lower inductor BL1A is made of, for example, a spiral wiring.

Subsequently, as shown in FIG. 6, in the semiconductor chip CHP1A, the wiring and an insulating film IF1A are formed so as to be in contact with the uppermost layer of the multilayer wiring layer MWL1A. Further, the upper inductor TL1A that is a component of the transformer TR1A is formed on an upper surface of the multilayer wiring layer MWL1A so as to be in contact with the uppermost layer of the multilayer wiring layer MWL1A. That is, the multilayer wiring layer MWL1A is formed between the upper inductor TL1A and the semiconductor substrate SUB1A.

An inorganic insulating film 40a is formed on the wiring including the pad formed so as to be in contact with the uppermost layer of the multilayer wiring layer MWL1A, on the upper inductor TL1A and on the insulating film IF1A. An organic insulating film 50a is formed on the inorganic insulating film 40a.

Here, the inorganic insulating film 40a is formed of a silicon nitride film. On the other hand, the organic insulating film 50a is formed of a polyimide resin film.

The organic insulating film 50a and the inorganic insulating film 40a are provided with a pad opening portion 60a so as to penetrate through the organic insulating film 50a and the inorganic insulating film 40a in order to expose the surface of the pad which is a component of the upper inductor TL1A.

Next, the high-side gate driver GD1, the receiving circuit RX1A, the transmitting circuit TX2A, the temperature detecting unit 20A, and the current detecting unit 30A shown in FIG. 4 are formed in the semiconductor chip CHP2A. As shown in FIG. 6, the semiconductor chip CHP2A includes a semiconductor substrate SUB2A and a multilayer wiring layer MWL2A formed on the semiconductor substrate SUB2A.

A plurality of transistors QB are formed on the semiconductor substrate SUB2A. The multilayer wiring layer MWL2A is formed over the semiconductor substrate SUB2A on which the plurality of transistors QB are formed. In the multilayer wiring layer MWL2A, a plurality of interlayer insulating films and a plurality of wirings are laminated. The wiring is formed in each layer of the multilayer wiring layer MWL2A. The wiring is electrically connected to the transistor QB. The transistor QB and the wiring electrically connected to each other configure the high-side gate driver GD1, the receiving circuit RX1A, the transmitting circuit TX2A, the temperature detecting unit 20A, and the current detecting unit 30A.

Then, the wiring including the pad and an insulating film IF2A are formed so as to be in contact with the uppermost layer of the multilayer wiring layer MWL2A. Further, an inorganic insulating film 40b is formed on the wiring including the pad formed so as to be in contact with the uppermost layer of the multilayer wiring layer MWL2A and on the insulating film IF2A. An organic insulating film 50b is formed on the inorganic insulating film 40b.

Here, the inorganic insulating film 40b is formed of a silicon nitride film. On the other hand, the organic insulating film 50b is formed of a polyimide resin film. The organic insulating film 50b and the inorganic insulating film 40b are provided with a pad opening portion 60b so as to penetrate through the organic insulating film 50b and the inorganic insulating film 40b in order to expose the surface of the pad.

Next, as shown in FIG. 6, the upper inductor TL1A formed in the semiconductor chip CHP1A is electrically connected to the wiring (pad) disposed so as to be in contact with the uppermost layer of the multilayer wiring layer MWL2A of the semiconductor chip CHP2A via, for example, a bonding wire W1. Specifically, a pad, which is a component of the upper inductor TL1A exposed from the pad opening portion 60a, and a pad exposed from the pad opening portion 60b are connected to each other via the bonding wire W1. The upper inductor TL1A formed in the semiconductor chip CHP1A includes, for example, the pad and the spiral wiring connected to the pad.

The semiconductor chip CHP1A and the semiconductor chip CHP2A configured as described above are covered with, for example, a mold resin MR1 made of an epoxy resin. As described above, the first semiconductor device SA1 of the two-chip configuration according to the first embodiment is configured.

Further, the configuration of the first semiconductor device SA1 according to the first embodiment will be described.

As shown in FIG. 6, the semiconductor chip CHP1A is provided with the upper inductor TL1A that is a component of the transformer TR1A (refer to FIG. 4) that performs non-contact communication between different potentials. The upper inductor TL1A is electrically connected to the wiring that is present in the multilayer wiring layer MWL2A of the semiconductor chip CHP2A. A second potential, which is a reference potential of about 800 V, is applied to the upper inductor TL1A. Specifically, the first semiconductor device SA1 according to the first embodiment includes the semiconductor chip CHP2A including a circuit (second circuit portion) applying the second potential to the upper inductor TL1A. The upper inductor TL1A formed in the semiconductor chip CHP1A is electrically connected to the circuit formed in the semiconductor chip CHP2A via the bonding wire W1 which is an exemplary conductive member. Accordingly, the second potential outputted from the circuit formed in the semiconductor chip CHP2A is applied to the upper inductor TL1A.

The semiconductor chip CHP1A is provided with the lower inductor BL1A and also includes a circuit (first circuit portion) applying a first potential, which is a reference potential of about 0 V, to the lower inductor BL1A. Accordingly, the first potential outputted from the circuit formed in the semiconductor chip CHP1A is applied to the lower inductor BL1A. Consequently, the second potential is applied to the upper inductor TL1A, while the first potential is applied to the lower inductor BL1A.

Here, the upper inductor TL1A is formed so as to be magnetically coupled to the lower inductor BL1A to which the first potential different from the second potential is applied in the thickness direction of the semiconductor chip CHP1A. Specifically, the upper inductor TL1A is formed in contact with the uppermost layer of the multilayer wiring layer MWL1A, while the lower inductor BL1A is formed in the multilayer wiring layer MWL1A. Thus, the upper inductor TL1A and the lower inductor BL1A are configured to be magnetically coupled to each other.

### Configuration of Second Semiconductor Device

Next, the configuration of the second semiconductor device SA2 will be described.

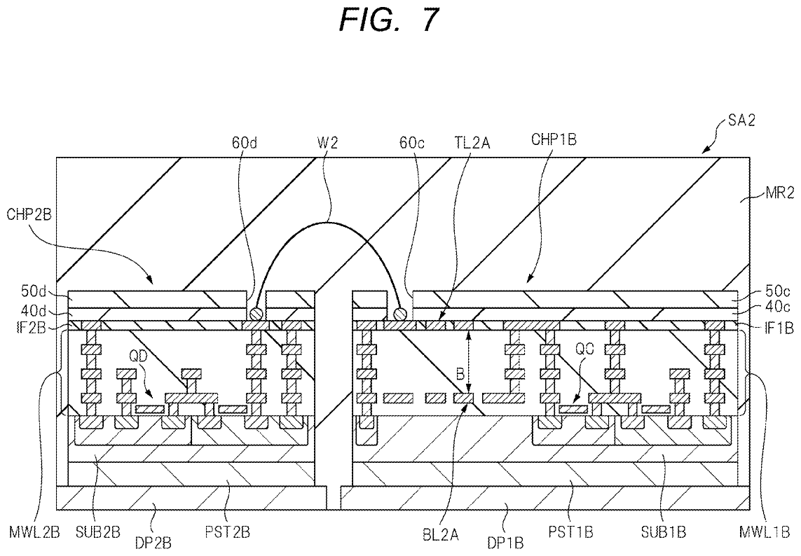

FIG. 7 is a cross-sectional view showing the configuration of the second semiconductor device SA2.

In FIG. 7, the second semiconductor device SA2 includes the semiconductor chip CHP1B and the semiconductor chip CHP2B. That is, the semiconductor device SA2 includes a two-chip configuration. The semiconductor chip CHP1B is mounted, for example, on a die pad DP1B that is a chip mounting portion via a conductive adhesive PST1B. On the other hand, the semiconductor chip CHP2B is mounted, for example, on a die pad DP2B which is a chip mounting portion via a conductive adhesive PST2B.

Here, each of the die pad DP1B and the die pad DP2B is made of, for example, a copper material. Each of the conductive adhesive PST1B and the conductive adhesive PST2B is made of, for example, silver-paste or solder.

The transmitting circuit TX1B, the receiving circuit RX2B, and the transformer TR2A shown in FIG. 5 are formed in the semiconductor chip CHP1B. As shown in FIG. 7, the semiconductor chip CHP1B includes a semiconductor substrate SUB1B and a multilayer wiring layer MWL1B formed on the semiconductor substrate SUB1B. A plurality of transistors QC are formed on the semiconductor substrate SUB1B. The multilayer wiring layer MWL1B is formed over the semiconductor substrate SUB1B on which the plurality of transistors QC are formed. The lowermost layer of the multilayer wiring layer MWL1B is in contact with the semiconductor substrate SUB1B.

In the multilayer wiring layer MWL1B, a plurality of interlayer insulating films and a plurality of wirings are laminated. The wiring is formed in each layer of the multilayer wiring layer MWL1B. The wiring is electrically connected to the transistor QC. The transistor QC and the wiring electrically connected to each other configure the transmitting circuit TX1B and the receiving circuit RX2B.

In addition to the wiring, the multilayer wiring layer MWL1B also includes the lower inductor BL2A which is a component of the transformer TR2A. The lower inductor BL2A is made of, for example, a spiral wiring.

Subsequently, as shown in FIG. 7, in the semiconductor chip CHP1B, the wiring and an insulating film IF1B are formed so as to be in contact with the uppermost layer of the multilayer wiring layer MWL1B. Further, the upper inductor TL2A that is a component of the transformer TR2A is formed on an upper surface of the multilayer wiring layer MWL1B so as to be in contact with the uppermost layer of the multilayer wiring layer MWL1B. That is, the multilayer wiring layer MWL1B is formed between the upper inductor TL2A and the semiconductor substrate SUB1B.

An inorganic insulating film 40c is formed on the wiring including the pad formed so as to be in contact with the uppermost layer of the multilayer wiring layer MWL1B, on the upper inductor TL2A and on the insulating film IF1B. An organic insulating film 50c is formed on the inorganic insulating film 40c.

Here, the inorganic insulating film 40c is formed of a silicon nitride film. On the other hand, the organic insulating film 50c is formed of a polyimide resin film.

The organic insulating film 50c and the inorganic insulating film 40c are provided with a pad opening portion 60c so as to penetrate through the organic insulating film 50c and the inorganic insulating film 40c in order to expose the surface of the pad which is a component of the upper inductor TL2A.

Next, the low-side gate driver GD2, the receiving circuit RX1B, the transmitting circuit TX2B, the temperature detecting unit 20B, and the current detecting unit 30B shown in FIG. 5 are formed in the semiconductor chip CHP2B. As shown in FIG. 7, the semiconductor chip CHP2B includes a semiconductor substrate SUB2B and a multilayer wiring layer MWL2B formed on the semiconductor substrate SUB2B.

A plurality of transistors QD are formed in the semiconductor substrate SUB2B. The multilayer wiring layer MWL2B is formed over the semiconductor substrate SUB2B on which the plurality of transistors QD are formed. In the multilayer wiring layer MWL2B, a plurality of interlayer insulating films and a plurality of wirings are laminated. The wiring is formed in each layer of the multilayer wiring layer MWL2B. The wiring is electrically connected to the transistor QD. The transistor QD and the wiring electrically connected to each other configure the low-side gate driver GD2, the receiving circuit RX1B, the transmitting circuit TX2B, the temperature detecting unit 20B, and the current detecting unit 30B.

Then, the wiring including the pad and an insulating film IF2B are formed so as to be in contact with the uppermost layer of the multilayer wiring layer MWL2B. Further, an inorganic insulating film 40d is formed on the wiring including the pad formed so as to be in contact with the uppermost layer of the multilayer wiring layer MWL2B and on the insulating film IF2B. An organic insulating film 50d is formed on the inorganic insulating film 40d.

Here, the inorganic insulating film 40d is formed of a silicon nitride film. On the other hand, the organic insulating film 50d is formed of a polyimide resin film. The organic insulating film 50d and the inorganic insulating film 40d are provided with a pad opening portion 60d so as to penetrate through the organic insulating film 50d and the inorganic insulating film 40d in order to expose the surface of the pad.

Next, as shown in FIG. 7, the upper inductor TL2A formed in the semiconductor chip CHP1B is electrically connected to the wiring (pad) disposed so as to be in contact with the uppermost layer of the multilayer wiring layer MWL2B of the semiconductor chip CHP2B via, for example, a bonding wire W2. Specifically, a pad, which is a component of the upper inductor TL2A exposed from the pad opening portion 60c, and a pad exposed from the pad opening portion 60d are connected to each other via the bonding wire W2. The upper inductor TL2A formed in the semiconductor chip CHP1B includes, for example, the pad and the spiral wiring connected to the pad.

The semiconductor chip CHP1B and the semiconductor chip CHP2B configured as described above are covered with, for example, a mold resin MR2 made of an epoxy resin. The second semiconductor device SA2 of the two-chip configuration in the first embodiment is configured as described above.

Further, the configuration of the second semiconductor device SA2 according to the first embodiment will be described.

As shown in FIG. 7, the semiconductor chip CHP1B is provided with the upper inductor TL2A that is a component of the transformer TR2A (refer to FIG. 5) that performs non-contact communication between different potentials. The upper inductor TL2A is electrically connected to the wiring that is present in the multilayer wiring layer MWL2B formed in the semiconductor chip CHP2B. A fourth potential, which is a reference potential of about several tens of volts, is applied to the upper inductor TL2A. Specifically, the second semiconductor device SA2 according to the first embodiment includes the semiconductor chip CHP2B including a circuit (fourth circuit portion) applying the fourth potential to the upper inductor TL2A. The upper inductor TL2A formed in the semiconductor chip CHP1B is electrically connected to the circuit formed in the semiconductor chip CHP2B via the bonding wire W2, which is an exemplary conductive member. As a result, the fourth potential is applied to the upper inductor TL2A from the circuit formed in the semiconductor chip CHP2B.

The semiconductor chip CHP1B is provided with the lower inductor BL2A and also includes a circuit (third circuit portion) that applies a third potential, which is a reference potential of about 0 V, to the lower inductor BL2A. As a result, the third potential outputted from the circuit formed in the semiconductor chip CHP1B is applied to the lower inductor BL2A. Consequently, the fourth potential is applied to the upper inductor TL2A, while the third potential is applied to the lower inductor BL2A.

Here, the upper inductor TL2A is formed so as to be magnetically coupled to the lower inductor BL2A to which the third potential different from the fourth potential is applied in the thickness direction of the semiconductor chip CHP1B. Specifically, the upper inductor TL2A is formed in contact with the uppermost layer of the multilayer wiring layer MWL1B, while the lower inductor BL2A is formed in the multilayer wiring layer MWL1B. Thus, the upper inductor TL2A and the lower inductor BL2A are configured to be magnetically coupled to each other.

### Configuration of Electronic Device

Next, a configuration of the electronic device will be described.

The electronic device includes the first semiconductor device SA1 shown in FIG. 6 and the second semiconductor device SA2 shown in FIG. 7. Specifically, the electronic device is configured to include the first semiconductor device SA1 including the semiconductor chip CHP1A and the semiconductor chip CHP2A, and the second semiconductor device SA2 including the semiconductor chip CHP1B and the semiconductor chip CHP2B.

Here, the semiconductor chip CHP1A includes the transformer TR1A that performs non-contact communication between the first potential and the second potential. On the other hand, the semiconductor chip CHP1B includes the transformer TR2A that performs non-contact communication between the third potential and the fourth potential. Here, the difference between the first potential and the second potential is greater than the difference between the third potential and the fourth potential. Therefore, the breakdown voltage of the transformer TR1A needs to be greater than the breakdown voltage of the transformer TR2A. In other words, the breakdown voltage of the transformer TR2A can be set lower than the breakdown voltage of the transformer TR1A.

The transformer TR1A includes the lower inductor BL1A, the upper inductor TL1A, and a first insulating layer interposed between the lower inductor BL1A and the upper inductor TL1A. The first insulating layer may be formed of one insulating layer or may be formed of multilayer insulating layers. On the other hand, the transformer TR2A includes the lower inductor BL2A, the upper inductor TL2A, and a second insulating layer interposed between the lower inductor BL2A and the upper inductor TL2A. Here, the second insulating layer may be formed of one insulating layer or may be formed of multilayer insulating layers.

Here, the second distance (“B”) between the lower inductor BL2A and the upper inductor TL2A shown in FIG. 5 and FIG. 7 is smaller than the first distance (“A”) between the lower inductor BL1A and the upper inductor TL1A shown in FIG. 4 and FIG. 6.

In another aspect, in FIG. 6, the semiconductor chip CHP1A includes the multilayer wiring layer MWL1A (first multilayer wiring layer). The lower inductor BL1A is formed in the multilayer wiring layer MWL1A. On the other hand, the upper inductor TL1A is formed on the multilayer wiring layer MWL1A. In contrast, in FIG. 7, the semiconductor chip CHP1B includes the multilayer wiring layer MWL1B (second multilayer wiring layer). The lower inductor BL2A is formed in the multilayer wiring layer MWL1B. On the other hand, the upper inductor TL2A is formed on the multilayer wiring layer MWL1B. Here, the thickness of the multilayer wiring layer MWL1B is smaller than the thickness of the multilayer wiring layer MWL1A.

The electronic device EA includes, for example, as shown in FIG. 3, the first semiconductor device SA1 configuring the high-side unit HSU and the second semiconductor device SA2 configuring the low-side unit LSU.

The high-side unit HSU includes a first circuit portion capable of applying the first potential to the lower inductor BL1A, a second circuit portion capable of applying the second potential to the upper inductor TL1A, and the transformer TR1A including the lower inductor BL1A and the upper inductor TL1A. On the other hand, the low-side unit LSU includes a third circuit portion capable of applying the third potential to the lower inductor BL2A, a fourth circuit portion capable of applying the fourth potential to the upper inductor TL2A, and the transformer TR2A including the lower inductor BL2A and the upper inductor TL2A.

Here, for example, as shown in FIG. 4 and FIG. 6, the first semiconductor device SA1 includes a two-chip configuration including the semiconductor chip CHP1A (first semiconductor chip) and the semiconductor chip CHP2A (high-side chip). The first circuit portion and the transformer TR1A are formed in the semiconductor chip CHP1A (first semiconductor chip). On the other hand, the second circuit portion is formed in the semiconductor chip CHP2A (high-side chip).

For example, the first circuit portion is configured by the transmitting circuit TX1A shown in FIG. 4, while the second circuit portion is configured by the receiving circuit RX1A shown in FIG. 4.

Next, as shown in FIG. 5 and FIG. 7, the second semiconductor device SA2 includes a two-chip configuration including the semiconductor chip CHP1B (second semiconductor chip) and the semiconductor chip CHP2B (low-side chip). The third circuit portion and the transformer TR2A are formed in the semiconductor chip CHP1B (second semiconductor chip). On the other hand, the fourth circuit portion is formed in the semiconductor chip CHP2B (low-side chip).

For example, the third circuit portion is configured by the transmitting circuit TX1B shown in FIG. 5, while the fourth circuit portion is configured by the receiving circuit RX1B shown in FIG. 5.

The electronic device EA is configured as described above.

### Features in First Embodiment

Subsequently, the feature points in the first embodiment will be described.

The feature point of the first embodiment is that, for example, as shown in FIG. 4 and FIG. 5, the structure of the transformer TR1A included in the high-side unit HSU and the structure of the transformer TR2A included in the low-side unit LSU are different from each other. In the first embodiment, the first distance between the lower inductor BL1A and the upper inductor TL1A, which are components of the transformer TR1A, is set to “A”, and the second distance between the lower inductor BL2A and the upper inductor TL2A, which are components of the transformer TR2A, is set to “B”. In this case, the feature point is that “B” is smaller than “A” (see also FIG. 6 and FIG. 7).

Thus, the feature point according to the first embodiment can reduce the manufacturing cost of the electronic device. This point will be described below.

For example, the transformer TR1A formed between the MCU 100 handling a low potential (several V) and the high-side gate driver GD1 handling a high potential (several hundred V) is required to have a high breakdown voltage. On the other hand, the transformer TR2A formed between the MCU 100 handling the low potential (several V) and the low-side gate driver GD2 handling the potential (several tens V) is not required to have a breakdown voltage higher than that of the transformer TR1A.

In this regard, for example, it is considered that the first distance between the lower inductor BL1A and the upper inductor TL1A of the transformer TR1A formed in the high-side unit HSU and the second distance between the lower inductor BL2A and the upper inductor TL2A of the transformer TR2A formed in the low-side unit LSU are equal.

In this case, the first distance and the second distance equal to each other are designed to be a distance that can ensure a high breakdown voltage of the transformer TR1A formed in the high-side unit HSU.

Then, in the transformer TR2A formed in the low-side unit LSU, a more breakdown voltage than necessary is ensured. That is, when the first distance and the second distance are made equal, the second distance is greater than a sufficient distance necessary for securing the breakdown voltage. Consequently, the performance of the transformer TR2A formed in the low-side unit LSU becomes excessive. In other words, more performance than necessary is added in the transformer TR2A. That is, if the first distance in the transformer TR1A and the second distance in the transformer TR2A are made equal to each other, the distance in the transformer is necessarily designed to meet the demanding specifications. Consequently, more performance than necessary is added in the transformer TR2A with a moderate demand.

This means that manufacturing of the transformer TR2A with a moderate demand for the breakdown voltage formed in the low-side unit LSU requires excess manufacturing cost. Therefore, designing the first distance and the second distance equally is not desirable from the viewpoint of reducing the manufacturing cost of the transformer TR2A formed in the low-side unit LSU and, consequently, the manufacturing cost of the electronic device.

Therefore, in the first embodiment, it is assumed that the structure of the transformer TR1A and the structure of the transformer TR2A are different from each other. In the first embodiment, each of the transformer TR1A and the transformer TR2A includes a configuration capable of exhibiting enough performance to satisfy the breakdown voltage required for each of them. Specifically, the feature point of the first embodiment is that the second distance (“B”) of the transformer TR2A formed in the low-side unit LSU is made smaller than the first distance (“A”) of the transformer TR1A formed in the high-side unit HSU. The above-described basic concept is embodied by this feature point.

As a consequence of embodying this feature point, for example, as shown in FIG. 6 and FIG. 7, the thickness of the multilayer wiring layer MWL1B is smaller than the thickness of the multilayer wiring layer MWL1A. As a result, reducing the thickness of the multilayer wiring layer MWL1B can reduce the manufacturing cost.

From another point of view, the number of layers of the multilayer wiring layer MWL1B can be reduced, for example, as a consequence of embodying this feature point. Therefore, according to the feature point, reducing the number of layers of the multilayer wiring layer MWL1B can reduce the manufacturing cost.

That is, according to the feature point, as a structure of the transformer TR2A formed in the low-side unit LSU, a structure (second distance B) including sufficient performance required to satisfy the breakdown voltage required for the transformer TR2A is adopted instead of adopting a structure (first distance A) designed in accordance with the specifications of the transformer TR1A with strict demands regarding the breakdown voltage. Therefore, according to the feature point, it is possible to prevent excessive performance from being added unnecessarily to the transformer TR2A with a moderate demand regarding the breakdown voltage. Therefore, the manufacturing cost of the electronic device can be reduced.

Configuration Derived from Features

The above-described feature point means that the communication distance between the lower inductor BL2A and the upper inductor TL2A in the transformer TR2A is shorter than the communication distance between the lower inductor BL1A and the upper inductor TL1A in the transformer TR1A.

Therefore, even if the coupling coefficient of the transformer TR2A formed in the low-side unit LSU is smaller than the coupling coefficient of the transformer TR1A formed in the high-side unit HSU, it is possible to secure the communication qualities in the transformer TR2A.

That is, when the above-described feature point is adopted, the coupling coefficient of the transformer TR2A formed in the low-side unit LSU can be made smaller than the coupling coefficient of the transformer TR1A formed in the high-side unit HSU. Therefore, adopting the configuration in which the coupling coefficient is reduced can further reduce the manufacturing cost.

Hereinafter, the configuration for reducing the coupling coefficient will be described.

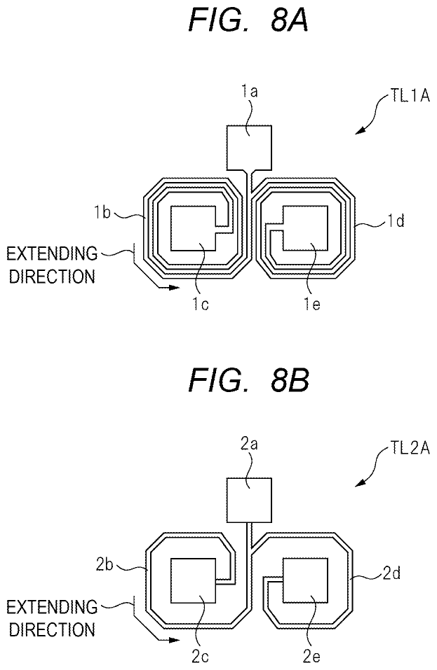

FIG. 8A is a schematic diagram showing a configuration of the upper inductor TL1A that is a component of the transformer TR1A formed in the high-side unit HSU. On the other hand, FIG. 8B is a schematic diagram showing a configuration of the upper inductor TL2A that is a component of the transformer TR2A formed in the low-side unit LSU.

In FIG. 8A, the upper inductor TL1A is configured to include, for example, a center tap pad 1a, a spiral wiring 1b which is an inductor wiring, a transpad 1c, a spiral wiring 1d which is an inductor wiring, and a transpad 1e corresponding to a pair of differential wirings. On the other hand, in FIG. 8B, the upper inductor TL2A is configured to include, for example, a center tap pad 2a, a spiral wiring 2b that is an inductor wiring, a transpad 2c, a spiral wiring 2d that is an inductor wiring, and a transpad 2e corresponding to a pair of differential wirings.

Here, for example, in the transformer TR1A, the configuration of the upper inductor TL1A shown in FIG. 8A is adopted. On the other hand, the coupling coefficient of the transformer TR2A formed in the low-side unit LSU is made smaller than the coupling coefficient of the transformer TR1A formed in the high-side unit HSU. Therefore, in the transformer TR2A, the configuration of the upper inductor TL2A shown in FIG. 8B is adopted.

(1) In order to make the coupling coefficient of the transformer TR2A smaller than the coupling coefficient of the transformer TR1A, for example, the number of turns of the spiral wiring 2b shown in FIG. 8B is smaller than the number of turns of the spiral wiring 1b shown in FIG. 8A. The number of turns of the spiral wiring 2d shown in FIG. 8B is smaller than the number of turns of the spiral wiring 1d shown in FIG. 8A. Thus, the coupling coefficient of the transformer TR2A becomes smaller than the coupling coefficient of the transformer TR1A, but the manufacturing cost of the transformer TR2A can be reduced by the smaller number of turns.

(2) In order to make the coupling coefficient of the transformer TR2A smaller than the coupling coefficient of the transformer TR1A, for example, the length (length the extending direction) of the spiral wiring 2b shown in FIG. 8B is shorter than the length (length in the extending direction) of the spiral wiring 1b shown in FIG. 8A. The length of the spiral wiring 2d (length in the extending direction) shown in FIG. 8B is shorter than the length of the spiral wiring 1d (length in the extending direction) shown in FIG. 8A. Thus, the coupling coefficient of the transformer TR2A becomes smaller than the coupling coefficient of the transformer TR1A, but the manufacturing cost of the transformer TR2A can be reduced by an amount corresponding to a shortened length.

(3) In order to make the coupling coefficient of the transformer TR2A smaller than the coupling coefficient of the transformer TR1A, for example, the cross-sectional area in the cross section orthogonal to the extending direction of the spiral wiring 2b shown in FIG. 8B is smaller than the cross-sectional area in the cross section orthogonal to the extending direction of the spiral wiring 1b shown in FIG. 8A. The cross-sectional area in the cross section orthogonal to the extending direction of the spiral wiring 2d shown in FIG. 8B is smaller than the cross-sectional area in the cross section orthogonal to the extending direction of the spiral wiring 1d shown in FIG. 8A. Thus, the coupling coefficient of the transformer TR2A becomes smaller than the coupling coefficient of the transformer TR1A, but the manufacturing cost of the transformer TR2A can be reduced by the smaller chip size.

Here, the configuration of the upper inductor TL1A and the configuration of the upper inductor TL2A are described with reference to the upper inductor TL1A and the upper inductor TL2A. The same configuration difference can be applied to the configuration of the lower inductor BL1A and the configuration of the lower inductor BL2A. In particular, applying the difference between the configuration of FIG. 8A and the configuration of FIG. 8B to both the upper inductor and the lower inductor can further reduce the manufacturing cost.

### First Modified Example

In the present first modified example, an exemplary configuration of an isolator from a capacitor using a pair of capacitively coupled electrodes is described.

The electronic device in the present first modified example basically includes the first semiconductor device SA1 shown in FIG. 6 and the second semiconductor device SA2 shown in FIG. 7. Specifically, the electronic device is configured to include the first semiconductor device SA1 including the semiconductor chip CHP1A and the semiconductor chip CHP2A, and the second semiconductor device SA2 including the semiconductor chip CHP1B and the semiconductor chip CHP2B.

Here, the semiconductor chip CHP1A includes a first capacitor that performs non-contact communication between the first potential and the second potential. That is, the semiconductor chip CHP1A includes a first capacitor including a first lower electrode instead of the lower inductor BL1A shown in FIG. 6 and a first upper electrode instead of the upper inductor TL1A shown in FIG. 6. On the other hand, the semiconductor chip CHP1B includes a second capacitor that performs non-contact communication between the third potential and the fourth potential. That is, the semiconductor chip CHP1B includes a second capacitor including a second lower electrode instead of the lower inductor BL2A shown in FIG. 7 and a second upper electrode instead of the upper inductor TL2A shown in FIG. 7.

The difference between the first potential and the second potential is greater than the difference between the third potential and the fourth potential. Therefore, the breakdown voltage of the first capacitor needs to be greater than the breakdown voltage of the second capacitor. In other words, the breakdown voltage of the second capacitor can be set lower than the breakdown voltage of the first capacitor.

The first capacitor includes a first lower electrode, a first upper electrode, and a first capacitive insulating layer interposed between the first lower electrode and the first upper electrode. The first capacitive insulating layer may be formed of one insulating layer or may be formed of multilayer insulating layers. The first lower electrode and the first upper electrode are configured to be capacitively coupled to each other.

On the other hand, the second capacitor includes a second lower electrode, a second upper electrode, and a second capacitive insulating layer interposed between the second lower electrode and the second upper electrode. The second capacitive insulating layer may be formed of one insulating layer or may be formed of multilayer insulating layers. The second lower electrode and the second upper electrode are configured to be capacitively coupled to each other.

Here, the second electrode distance between the second lower electrode and the second upper electrode is smaller than the first electrode distance between the first lower electrode and the first upper electrode.

In another aspect, in FIG. 6, the semiconductor chip CHP1A includes the multilayer wiring layer MWL1A (first multilayer wiring layer). The first lower electrode instead of the lower inductor BL1A is formed in the multilayer wiring layer MWL1A. On the other hand, the first upper electrode instead of the upper inductor TL1A is formed on the multilayer wiring layer MWL1A.

In contrast, in FIG. 7, the semiconductor chip CHP1B includes the multilayer wiring layer MWL1B (second multilayer wiring layer). The second lower electrode instead of the lower inductor BL2A is formed in the multilayer wiring layer MWL1B. On the other hand, the second upper electrode instead of the upper inductor TL2A is formed on the multilayer wiring layer MWL1B. The thickness of the multilayer wiring layer MWL1B is smaller than the thickness of the multilayer wiring layer MWL1A.

The electronic device EA includes, for example, as shown in FIG. 3, the first semiconductor device SA1 configuring the high-side unit HSU and the second semiconductor device SA2 configuring the low-side unit LSU.

The high-side unit HSU includes a first circuit portion capable of applying the first potential to the first lower electrode, a first capacitor including the first lower electrode and the first upper electrode, and a second circuit portion capable of applying the second potential to the first upper electrode. On the other hand, the low-side unit LSU includes a third circuit portion capable of applying the third potential to the second lower electrode, a second capacitor including the second lower electrode and the second upper electrode, and a fourth circuit portion capable of applying the fourth potential to the second upper electrode.

Here, for example, the first semiconductor device SA1 includes a two-chip configuration including the semiconductor chip CHP1A (first semiconductor chip) and the semiconductor chip CHP2A (high-side chip). The first circuit portion and the first capacitor are formed in the semiconductor chip CHP1A (first semiconductor chip). On the other hand, the second circuit portion is formed in the semiconductor chip CHP2A (high-side chip). For example, the first circuit portion is configured by the transmitting circuit TX1A shown in FIG. 4. On the other hand, the second circuit portion is configured by the receiving circuit RX1A shown in FIG. 4.

Next, the second semiconductor device SA2 includes a two-chip configuration including the semiconductor chip CHP1B (second semiconductor chip) and the semiconductor chip CHP2B (low-side chip). The third circuit portion and the second capacitor are formed in the semiconductor chip CHP1B (second semiconductor chip). On the other hand, the fourth circuit portion is formed in the semiconductor chip CHP2B (low-side chip). For example, the third circuit portion is configured by the transmitting circuit TX1B shown in FIG. 5. On the other hand, the fourth circuit portion is configured by the receiving circuit RX1B shown in FIG. 5.

The electronic device EA in the present first modified example is configured as described above.

The feature point of the present first modified example is that, for example, the structure of the first capacitor included in the high-side unit HSU is different from the structure of the second capacitor included in the low-side unit LSU. Specifically, the first electrode distance between the first lower electrode and the first upper electrode, which are components of the first capacitor, is referred to as “C”, and the second electrode distance between the second lower electrode and the second upper electrode, which are components of the second capacitor, is referred to as “D”. In this case, the feature point in the present first modified example is that “D” is smaller than “C”. Thus, the present first modified example can reduce the manufacturing cost of the electronic device. In other words, for example, in FIG. 6 and FIG. 7 showing the basic configuration of the present first modified example, the thickness of the multilayer wiring layer MWL1B becomes smaller than the thickness of the multilayer wiring layer MWL1A. Accordingly, according to the present first modified example, reducing the thickness of the multilayer wiring layer MWL1B can reduce the manufacturing cost.

Further, from another viewpoint, for example, the present first modified example can reduce the number of layers of the multilayer wiring layer MWL1B. Therefore, according to the present first modified example, reducing the number of layers of the multilayer wiring layer MWL1B can reduce the manufacturing cost.

When the above-described feature point is adopted, the coupling capacitance of the second capacitor formed in the low-side unit LSU can be made smaller than the coupling capacitance of the first capacitor formed in the high-side unit HSU. Therefore, adopting a configuration in which the coupling capacitance is reduced can further reduce the manufacturing cost. Specifically, since the coupling capacitance of the second capacitor is made smaller than the coupling capacitance of the first capacitor, for example, the electrode area of the second lower electrode is smaller than the electrode area of the first lower electrode. Thus, the coupling capacitance of the second capacitor can be made smaller than the coupling capacitance of the first capacitor. The reduction in the electrode area can reduce the manufacturing cost of the second capacitor. Here, the “electrode area” refers to, for example, the area of the surfaces of the pair of first lower electrode and the first upper electrode that face each other.

Here, the difference between the configuration of the first lower electrode and the configuration of the second lower electrode is described. The same configuration difference can be applied to the configuration of the first upper electrode and the configuration of the second upper electrode. In particular, applying the difference of the above-described configuration to both the lower electrode and the upper electrode can reduce the manufacturing cost.

### Second Embodiment

### Three-Chip Configuration

In the first semiconductor device SA1 and the second semiconductor device SA2 in the first embodiment described above, a two-chip configuration is adopted. However, for example, in the first semiconductor device SA1 of the two-chip configuration, since the transformer TR1A, the transmitting circuit TX1A, and the receiving circuit RX2A are formed in one semiconductor chip, the manufacturing process of the semiconductor chip CHP1A is complicated. Alternatively, in the first semiconductor device SA1 of the two-chip configuration, the transformer TR1B, the high-side gate driver GD1, the receiving circuit RX1A, the transmitting circuit TX2A, the temperature detecting unit 20A, and the current detecting unit 30A are formed in one semiconductor chip, the manufacturing process of the semiconductor chip CHP2A is complicated. As a consequence, the manufacturing costs of the semiconductor chip CHP1A and the semiconductor chip CHP2A may increase.

Similarly, in the second semiconductor device SA2 of the two-chip configuration, for example, since the transformer TR2A, the transmitting circuit TX1B, and the receiving circuit RX2B are formed in one semiconductor chip, the manufacturing process of the semiconductor chip CHP1B is complicated. Alternatively, in the second semiconductor device SA2 of the two-chip configuration, the transformer TR2B, the low-side gate driver GD2, the receiving circuit RX1B, the transmitting circuit TX2B, the temperature detecting unit 20B, and the current detecting unit 30B are formed in one semiconductor chip, the manufacturing process of the semiconductor chip CHP2B is complicated. As a consequence, the manufacturing costs of the semiconductor chip CHP1B and the semiconductor chip CHP2B may increase.

Therefore, it is studied that each of the first semiconductor device SA1 and the second semiconductor device SA2 described above is not configured as a two-chip configuration, but is configured as a three-chip configuration. Hereinafter, a novel three-chip configuration will be described.

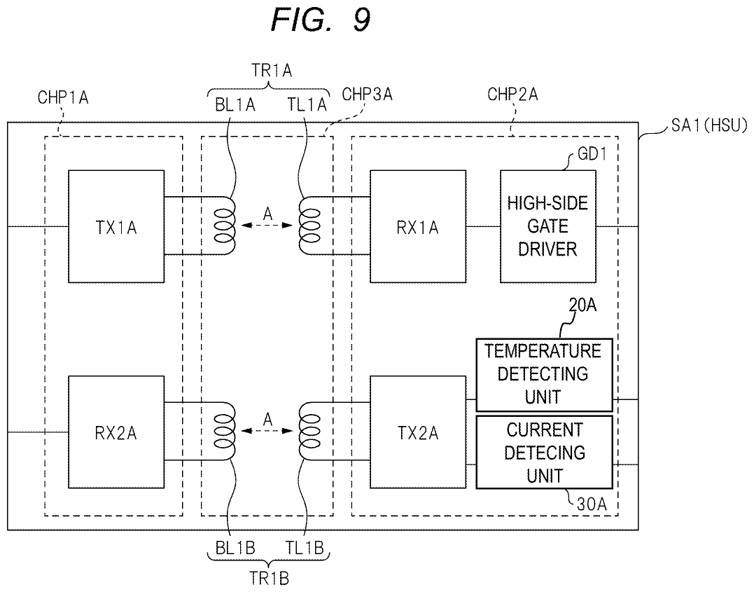

FIG. 9 is a diagram showing the first semiconductor device SA1 of the three-chip configuration.

In FIG. 9, the transmitting circuit TX1A and the receiving circuit RX2A are formed in the semiconductor chip CHP1A. In the semiconductor chip CHP2A, the high-side gate driver GD1, the receiving circuit RX1A, the transmitting circuit TX2A, the temperature detecting unit 20A, and the current detecting unit 30A are formed. On the other hand, the transformer TR1A and the transformer TR1B are formed in a semiconductor chip CHP3A.

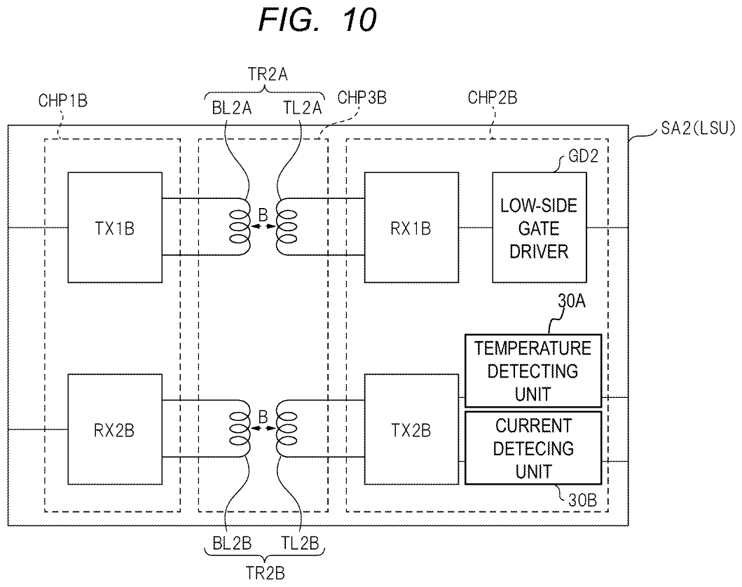

FIG. 10 is a diagram showing the second semiconductor device SA2 of the three-chip configuration.

In FIG. 10, the transmitting circuit TX1B and the receiving circuit RX2B are formed in the semiconductor chip CHP1B. The low-side gate driver GD2, the receiving circuit RX1B, the transmitting circuit TX2B, the temperature detecting unit 20B, and the current detecting unit 30B are formed in the semiconductor chip CHP2B. On the other hand, the transformer TR2A and the transformer TR2B are formed in a semiconductor chip CHP3B.

Thus, the first semiconductor device SA1 of the three-chip configuration includes the semiconductor chip CHP3A in which the transformer TR1A and the transformer TR1B are formed. The second semiconductor device SA2 of the three-chip configuration includes the semiconductor chip CHP3B in which the transformer TR2A and the transformer TR2B are formed.

That is, in the first semiconductor device SA1 of the three-chip configuration, the semiconductor chip CHP3A can be used regardless of the configuration of the semiconductor chip CHP1A and the semiconductor chip CHP2A. Similarly, in the second semiconductor device SA2 of the three-chip configuration, the semiconductor chip CHP3B can be used regardless of the configuration of the semiconductor chip CHP1B and the semiconductor chip CHP2B. Accordingly, the first semiconductor device SA1 of the three-chip configuration can increase the usable variation of the semiconductor chip CHP1A and the semiconductor chip CHP2A. In other words, the versatility of the semiconductor chip CHP3A in which the transformer TR1A and the transformer TR1B are formed can be improved. Further, the semiconductor chip CHP3A in which the transformer TR1A and the transformer TR1B are formed does not include a transistor. Therefore, the semiconductor chip CHP3A can be formed only by the wiring process, and thus the manufacturing process can be simplified. Therefore, the first semiconductor device SA1 of the three-chip configuration can reduce the manufacturing cost.

Similarly, the second semiconductor device SA2 of the three-chip configuration can increase the usable variation of the semiconductor chip CHP1B and the semiconductor chip CHP2B. In other words, the versatility of the semiconductor chip CHP3B in which the transformer TR2A and the transformer TR2B are formed can be improved. Further, the semiconductor chip CHP3B in which the transformer TR2A and the transformer TR2B are formed does not include a transistor. Therefore, the semiconductor chip CHP3B can be formed only by the wiring process, and thus the manufacturing process can be simplified. Therefore, the second semiconductor device SA2 of the three-chip configuration can reduce the manufacturing cost.

In the following description, the semiconductor chip CHP3A in which the transformer TR1A and the transformer TR1B are formed may be referred to as a “first transformer chip”. The semiconductor chip CHP3B in which the transformer TR2A and the transformer TR2B are formed may be referred to as a “second transformer chip”.

### Configuration of First Semiconductor Device

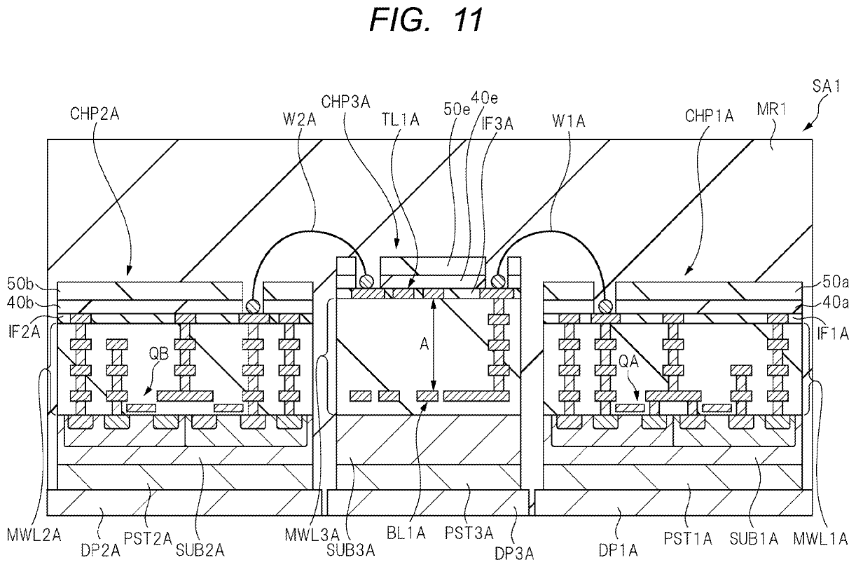

FIG. 11 is a cross-sectional view showing a configuration of the first semiconductor device SA1 in the second embodiment.

In FIG. 11, the first semiconductor device SA1 includes the semiconductor chip CHP1A, the semiconductor chip CHP2A, and the semiconductor chip CHP3A. That is, the first semiconductor device SA1 in the second embodiment shown in FIG. 11 includes the three-chip configuration.

The semiconductor chip CHP1A is mounted, for example, on the die pad DP1A that is a chip mounting portion via the conductive adhesive PST1A. On the other hand, the semiconductor chip CHP2A is mounted, for example, on the die pad DP2A which is a chip mounting portion via the conductive adhesive PST2A. Further, the semiconductor chip CHP3A is mounted, for example, on a die pad DP3A which is a chip mounting portion via a conductive adhesive PST3A.

Here, the die pad DP1A, the die pad DP2A, and the die pad DP3A are made of, for example, copper material. The conductive adhesive PST1A, the conductive adhesive PST2A, and the conductive adhesive PST3A are made of, for example, silver-paste or solder.

The transmitting circuit TX1A and the receiving circuit RX2A shown in FIG. 9 are formed in the semiconductor chip CHP1A. As shown in FIG. 11, the semiconductor chip CHP1A includes the semiconductor substrate SUB1A and the multilayer wiring layer MWL1A formed on the semiconductor substrate SUB1A.

The plurality of transistors QA are formed on the semiconductor substrate SUB1A. The multilayer wiring layer MWL1A is formed over the semiconductor substrate SUB1A on which the plurality of transistors QA are formed. In the multilayer wiring layer MWL1A, a plurality of interlayer insulating films and a plurality of wirings are laminated. The wiring is formed in each layer of the multilayer wiring layer MWL1A. The wiring is electrically connected to the transistor QA. The transistor QA and the wiring electrically connected to each other configure the transmitting circuit TX1A and the receiving circuit RX2A.

Subsequently, as shown in FIG. 11, in the semiconductor chip CHP1A, the wiring and the insulating film IF1A are formed so as to be in contact with the uppermost layer of the multilayer wiring layer MWL1A. The inorganic insulating film 40a is formed on the wiring including the pad formed so as to be in contact with the uppermost layer of the multilayer wiring layer MWL1A and on the insulating film IF1A. The organic insulating film 50a is formed on the inorganic insulating film 40a. Here, the inorganic insulating film 40a is formed of a silicon nitride film. On the other hand, the organic insulating film 50a is formed of a polyimide resin film.

Next, in the semiconductor chip CHP2A, the transmitting circuit TX2A, the receiving circuit RX1A, the high-side gate driver GD1, the temperature detecting unit 20A, and the current detecting unit 30A shown in FIG. 9 are formed. As shown in FIG. 11, the semiconductor chip CHP2A includes the semiconductor substrate SUB2A and the multilayer wiring layer MWL2A formed on the semiconductor substrate SUB2A.

The plurality of transistors QB are formed in the semiconductor substrate SUB2A. The multilayer wiring layer MWL2A is formed over the semiconductor substrate SUB2A on which the plurality of transistors QB are formed. In the multilayer wiring layer MWL2A, a plurality of interlayer insulating films and a plurality of wirings are laminated. The wiring is formed in each layer of the multilayer wiring layer MWL2A. The wiring is electrically connected to the transistor QB. The transistor QB and the wiring electrically connected to each other configure the transmitting circuit TX2A, the receiving circuit RX1A, the high-side gate driver GD1, the temperature detecting unit 20A, and the current detecting unit 30A.

Subsequently, as shown in FIG. 11, in the semiconductor chip CHP2A, the wiring and the insulating film IF2A are formed so as to be in contact with the uppermost layer of the multilayer wiring layer MWL2A. The inorganic insulating film 40b is formed on the wiring including the pad formed so as to be in contact with the uppermost layer of the multilayer wiring layer MWL2A and on the insulating film IF2A. The organic insulating film 50b is formed on the inorganic insulating film 40b. Here, the inorganic insulating film 40b is formed of a silicon nitride film. On the other hand, the organic insulating film 50b is formed of a polyimide resin film.

Next, the transformer TR1A and the transformer TR1B shown in FIG. 9 are formed in the semiconductor chip CHP3A (“first transformer chip”). As shown in FIG. 11, the semiconductor chip CHP3A includes a semiconductor substrate SUB3A and a multilayer wiring layer MWL3A formed on the semiconductor substrate SUB3A. The lowermost layer of the multilayer wiring layer MWL3A is in contact with the semiconductor substrate SUB3A. In addition to the wiring, the multilayer wiring layer MWL3A includes the lower inductor BL1A that is a component of the transformer TR1A. The lower inductor BL1A is made of, for example, a spiral wiring.

Then, as shown in FIG. 11, in the semiconductor chip CHP3A, the wiring and an insulating film IF3A are formed so as to be in contact with the uppermost layer of the multilayer wiring layer MWL3A. Further, the upper inductor TL1A that is a component of the transformer TR1A is formed on an upper surface of the multilayer wiring layer MWL3A so as to be in contact with the uppermost layer of the multilayer wiring layer MWL3A. That is, the multilayer wiring layer MWL3A is formed between the upper inductor TL1A and the semiconductor substrate SUB3A.

Further, an inorganic insulating film 40e is formed on the wiring including the pad formed so as to be in contact with the uppermost layer of the multilayer wiring layer MWL3A, on the upper inductor TL1A and on the insulating film IF3A. An organic insulating film 50e is formed on the inorganic insulating film 40e. Here, the inorganic insulating film 40e is formed of a silicon nitride film. On the other hand, the organic insulating film 50e is formed of a polyimide resin film.

As shown in FIG. 11, the semiconductor chip CHP3A includes the upper inductor TL1A and the lower inductor BL1A, which are components of the transformer that performs non-contact communication between different potentials. The upper inductor TL1A is electrically connected to the wiring that is present in the multilayer wiring layer MWL2A formed in the semiconductor chip CHP2A. The second potential, which is a reference potential of about 800 V, is applied to the upper inductor TL1A. Specifically, the first semiconductor device SA1 according to the second embodiment includes the semiconductor chip CHP2A including a circuit (second circuit portion) applying the second potential to the upper inductor TL1A. The upper inductor TL1A formed in the semiconductor chip CHP3A is electrically connected to the circuit formed in the semiconductor chip CHP2A via a bonding wire W2A, which is an exemplary conductive member. Accordingly, the second potential outputted from the circuit formed in the semiconductor chip CHP2A is applied to the upper inductor TL1A.

The lower inductor BL1A is electrically connected to the wiring that is present in the multilayer wiring layer MWL1A formed in the semiconductor chip CHP1A. The first potential, which is a reference potential of about 0 V, is applied to the lower inductor BL1A. Specifically, the first semiconductor device SA1 according to the second embodiment includes the semiconductor chip CHP1A including a circuit (first circuit portion) applying the first potential to the lower inductor BL1A. The lower inductor BL1A formed in the semiconductor chip CHP3A is electrically connected to the circuit formed in the semiconductor chip CHP1A via a bonding wire W1A which is an exemplary conductive member. Accordingly, the first potential outputted from the circuit formed in the semiconductor chip CHP1A is applied to the lower inductor BL1A.

As described above, the first semiconductor device SA1 includes the semiconductor chip CHP1A (first high-side chip), the semiconductor chip CHP2A (second high-side chip), and the semiconductor chip CHP3A (first semiconductor chip). The first circuit portion is formed in the semiconductor chip CHP1A (first high-side chip). The second circuit portion is formed in the semiconductor chip CHP2A (second high-side chip). The transformer TR1A is formed in the semiconductor chip CHP3A (first semiconductor chip).

The upper inductor TL1A is formed so as to be magnetically coupled to the lower inductor BL1A to which the first potential different from the second potential is applied in the thickness direction of the semiconductor chip CHP3A. Specifically, the upper inductor TL1A is formed in contact with the uppermost layer of the multilayer wiring layer MWL3A, while the lower inductor BL1A is formed in the multilayer wiring layer MWL3A. Thus, the upper inductor TL1A and the lower inductor BL1A are configured to be magnetically coupled to each other.

As shown in FIG. 11, the semiconductor chip CHP1A, the semiconductor chip CHP2A, and the semiconductor chip CHP3A configured as described above are sealed with, for example, the mold resin MR1 made of an epoxy resin. In other words, the semiconductor chip CHP1A, the semiconductor chip CHP2A, and the semiconductor chip CHP3A are covered with the mold resin MR1. The first semiconductor device SA1 of the three-chip configuration is configured as described above.

### Configuration of Second Semiconductor Device

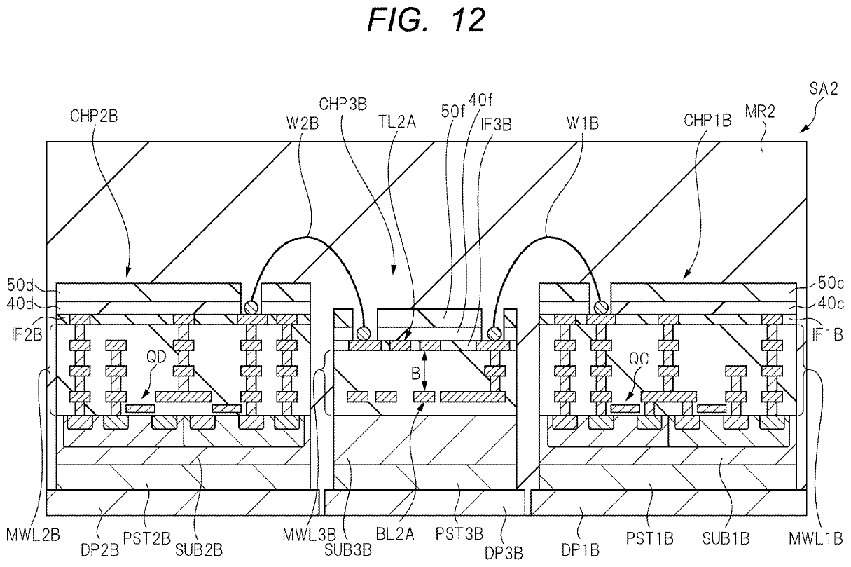

FIG. 12 is a cross-sectional view showing a configuration of the second semiconductor device SA2 in the second embodiment.

In FIG. 12, the second semiconductor device SA2 includes the semiconductor chip CHP1B, the semiconductor chip CHP2B, and the semiconductor chip CHP3B. That is, the second semiconductor device SA2 in the second embodiment shown in FIG. 12 includes a three-chip configuration.

The semiconductor chip CHP1B is mounted, for example, on the die pad non-contact that is a chip mounting portion via the conductive adhesive PST1B. On the other hand, the semiconductor chip CHP2B is mounted, for example, on the die pad DP2B which is a chip mounting portion via the conductive adhesive PST2B. Further, the semiconductor chip CHP3B is mounted, for example, on a die pad DP3B which is a chip mounting portion via a conductive adhesive PST3B.

Here, the die pad DP1B, the die pad DP2B, and the die pad DP3B are made of, for example, copper material. The conductive adhesive PST1B, the conductive adhesive PST2B, and the conductive adhesive PST3B are made of, for example, silver-paste or solder.

The transmitting circuit TX1B and the receiving circuit RX2B shown in FIG. 10 are formed in the semiconductor chip CHP1B. As shown in FIG. 12, the semiconductor chip CHP1B includes the semiconductor substrate SUB1B and the multilayer wiring layer MWL1B formed on the semiconductor substrate SUB1B.

The plurality of transistors QC are formed on the semiconductor substrate SUB1B. The multilayer wiring layer MWL1B is formed over the semiconductor substrate SUB1B on which the plurality of transistors QC are formed. In the multilayer wiring layer MWL1B, a plurality of interlayer insulating films and a plurality of wirings are laminated. The wiring is formed in each layer of the multilayer wiring layer MWL1B. The wiring is electrically connected to the transistor QC. The transistor QC and the wiring electrically connected to each other configure the transmitting circuit TX1B and the receiving circuit RX2B.

Subsequently, as shown in FIG. 12, in the semiconductor chip CHP1B, the wiring and the insulating film IF1B are formed so as to be in contact with the uppermost layer of the multilayer wiring layer MWL1B. The inorganic insulating film 40c is formed on the wiring including the pad formed so as to be in contact with the uppermost layer of the multilayer wiring layer MWL1B and on the insulating film IF1B. The organic insulating film 50c is formed on the inorganic insulating film 40c. Here, the inorganic insulating film 40c is formed of a silicon nitride film. On the other hand, the organic insulating film 50c is formed of a polyimide resin film.

Next, in the semiconductor chip CHP2B, the transmitting circuit TX2B, the receiving circuit RX1B, the low-side gate driver GD2, the temperature detecting unit 20B, and the current detecting unit 30B shown in FIG. 10 are formed. As shown in FIG. 12, the semiconductor chip CHP2B includes the semiconductor substrate SUB2B and the multilayer wiring layer MWL2B formed on the semiconductor substrate SUB2B.

The plurality of transistors QD are formed on the semiconductor substrate SUB2B. The multilayer wiring layer MWL2B is formed over the semiconductor substrate SUB2B on which the plurality of transistors QD are formed. In the multilayer wiring layer MWL2B, a plurality of interlayer insulating films and a plurality of wirings are laminated. The wiring is formed in each layer of the multilayer wiring layer MWL2B. The wiring is electrically connected to the transistor QD. The transistor QD and the wiring electrically connected to each other configure the transmitting circuit TX2B, the receiving circuit RX1B, the low-side gate driver GD2, the temperature detecting unit 20B, and the current detecting unit 30B.

Subsequently, as shown in FIG. 12, in the semiconductor chip CHP2B, the wiring and the insulating film IF2B are formed so as to be in contact with the uppermost layer of the multilayer wiring layer MWL2B. The inorganic insulating film 40d is formed on the wiring including the pad formed so as to be in contact with the uppermost layer of the multilayer wiring layer MWL2B and on the insulating film IF2B. The organic insulating film 50d is formed on the inorganic insulating film 40d. Here, the inorganic insulating film 40d is formed of a silicon nitride film. On the other hand, the organic insulating film 50d is formed of a polyimide resin film.

Next, the transformer TR2A and the transformer TR2B shown in FIG. 10 are formed in the semiconductor chip CHP3B (“second transformer chip”). As shown in FIG. 12, the semiconductor chip CHP3B includes a semiconductor substrate SUB3B and a multilayer wiring layer MWL3B formed on the semiconductor substrate SUB3B. The lowermost layer of the multilayer wiring layer MWL3B is in contact with the semiconductor substrate SUB3B. In addition to the wiring, the multilayer wiring layer MWL3B includes the lower inductor BL2A that is a component of the transformer TR2A. The lower inductor BL2A is made of, for example, a spiral wiring.

Then, as shown in FIG. 12, in the semiconductor chip CHP3B, the wiring and an insulating film IF3B are formed so as to be in contact with the uppermost layer of the multilayer wiring layer MWL3B. Further, the upper inductor TL2A that is a component of the transformer TR2A is formed on an upper surface of the multilayer wiring layer MWL3B so as to be in contact with the uppermost layer of the multilayer wiring layer MWL3B. That is, the multilayer wiring layer MWL3B is formed between the upper inductor TL2A and the semiconductor substrate SUB3B.

Further, an inorganic insulating film 40f is formed on the wiring including the pad formed so as to be in contact with the uppermost layer of the multilayer wiring layer MWL3B, on the upper inductor TL2A and on the insulating film IF3B. An organic insulating film 50f is formed on the inorganic insulating film 40f. Here, the inorganic insulating film 40f is formed of a silicon nitride film. On the other hand, the organic insulating film 50f is formed of a polyimide resin film.

As shown in FIG. 12, the semiconductor chip CHP3B includes the upper inductor TL2A and the lower inductor BL2A, which are components of the transformer that performs non-contact communication between different potentials. The upper inductor TL2A is electrically connected to the wiring that is present in the multilayer wiring layer MWL2B formed in the semiconductor chip CHP2B. The fourth potential, which is a reference potential of about several tens of volts, is applied to the upper inductor TL2A. Specifically, the second semiconductor device SA2 according to the second embodiment includes the semiconductor chip CHP2B including a circuit (fourth circuit portion) applying the fourth potential to the upper inductor TL2A. The upper inductor TL2A formed in the semiconductor chip CHP3B is electrically connected to the circuit formed in the semiconductor chip CHP2B via a bonding wire W2B, which is an exemplary conductive member. As a result, the fourth potential outputted from the circuit formed in the semiconductor chip CHP2B is applied to the upper inductor TL2A.

The lower inductor BL2A is electrically connected to the wiring that is present in the multilayer wiring layer MWL1B formed in the semiconductor chip CHP1B. The third potential, which is a reference potential of about 0 V, is applied to the lower inductor BL2A. Specifically, the second semiconductor device SA2 according to the second embodiment includes the semiconductor chip CHP1B including a circuit (third circuit portion) applying the third potential to the lower inductor BL2A. The lower inductor BL2A formed in the semiconductor chip CHP3B is electrically connected to the circuit formed in the semiconductor chip CHP1B via a bonding wire W1B which is an exemplary conductive member. As a result, the third potential outputted from the circuit formed in the semiconductor chip CHP1B is applied to the lower inductor BL2A.

As described above, the second semiconductor device SA2 includes the semiconductor chip CHP1B (first low-side chip), the semiconductor chip CHP2B (second low-side chip), and the semiconductor chip CHP3B (second semiconductor chip). The third circuit portion is formed in the semiconductor chip CHP1B (first low-side chip). The fourth circuit portion is formed in the semiconductor chip CHP2B (second low-side chip). The transformer TR2A is formed in the semiconductor chip CHP3B (second semiconductor chip).

The upper inductor TL2A is formed so as to be magnetically coupled to the lower inductor BL2A to which the third potential different from the fourth potential is applied in the thickness direction of the semiconductor chip CHP3B. Specifically, the upper inductor TL2A is formed so as to be in contact with the uppermost layer of the multilayer wiring layer MWL3B. On the other hand, the lower inductor BL2A is formed in the multilayer wiring layer MWL3B. Thus, the upper inductor TL2A and the lower inductor BL2A are configured to be magnetically coupled to each other.

As shown in FIG. 12, the semiconductor chip CHP1B, the semiconductor chip CHP2B, and the semiconductor chip CHP3B configured as described above are sealed with, for example, the mold resin MR2 made of an epoxy resin. In other words, the semiconductor chip CHP1B, the semiconductor chip CHP2B, and the semiconductor chip CHP3B are covered with the mold resin MR2. In this way, the second semiconductor device SA2 of the three-chip configuration is configured.

### Features in Second Embodiment

Next, the feature point in the second embodiment is explained.

The feature point of the second embodiment is that, for example, as shown in FIG. 9 and FIG. 10, the structure of the transformer TR1A included in the high-side unit HSU and the structure of the transformer TR2A included in the low-side unit LSU are different from each other. Specifically, in the second embodiment, the first distance between the lower inductor BL1A and the upper inductor TL1A, which are components of the transformer TR1A, is referred to “A”, and the second distance between the lower inductor BL2A and the upper inductor TL2A, which are components of the transformer TR2A, is referred to “B”. In this case, the feature point is that “B” is smaller than “A” (see also FIG. 11 and FIG. 12). The above-described basic concept is embodied by this feature.

As shown in FIG. 11 and FIG. 12, the thickness of the multilayer wiring layer MWL3B is smaller than the thickness of the multilayer wiring layer MWL3A. As a result, reducing the thickness of the multilayer wiring layer MWL3B can reduce the manufacturing cost.

From another point of view, the number of layers of the multilayer wiring layer MWL3B can be reduced, for example, as a consequence of embodying this feature. Therefore, according to the feature point, reducing the number of layers of the multilayer wiring layer MWL3B can reduce the manufacturing cost.

That is, according to the feature point, as a structure of the transformer TR2A formed in the low-side unit LSU, a structure (second distance B) including sufficient performance required to satisfy the breakdown voltage required for the transformer TR2A is adopted instead of adopting a structure (first distance A) designed in accordance with the specifications of the transformer TR1A with strict demands regarding the breakdown voltage. Therefore, the feature point can prevent excessive performance from being added to the transformer TR2A with a moderate demand for the breakdown voltage, and can reduce the manufacturing cost of the electronic device.

### Second Modified Example

In the three-chip configuration, instead of configuring an isolator from a transformer using a pair of inductors inductively coupled (magnetically coupled), an isolator may be configured from a capacitor using a pair of capacitively coupled electrodes. In this case, a first capacitor is formed in the semiconductor chip CHP3A. On the other hand, a second capacitor is formed in the semiconductor chip CHP3B.

Specifically, a first lower electrode and a first upper electrode configuring the first capacitor are formed in the semiconductor chip CHP3A. On the other hand, a second lower electrode and a second upper electrode configuring the second capacitor are formed in the semiconductor chip CHP3B. Here, the first electrode distance between the first lower electrode and the first upper electrode which are components of the first capacitor is referred to as “C”, and the second electrode distance between the second lower electrode and the second upper electrode which are components of the second capacitor is referred to as “D”. In this case, “D” is smaller than “C”. Thus, the present second modified example can reduce the manufacturing cost of the electronic device. In other words, for example, in FIG. 11 and FIG. 12 showing the basic configuration of the present second modified example, the thickness of the multilayer wiring layer MWL3B is smaller than the thickness of the multilayer wiring layer MWL3A. Accordingly, according to the present second modified example, reducing the thickness of the multilayer wiring layer MWL3B can reduce the manufacturing cost.

Further, from another viewpoint, for example, the present second modified example can reduce the number of layers of the multilayer wiring layer MWL3B. Therefore, according to the present second modified example, reducing the number of layers of the multilayer wiring layer MWL3B can reduce the manufacturing cost.

The invention made by the present inventor has been described above in detail based on the embodiment, but the present invention is not limited to the embodiment described above, and it is needless to say that various modifications can be made without departing from the gist thereof.

What is claimed is:

1. An electronic device comprising:
a first semiconductor device including a first semiconductor chip; and
a second semiconductor device including a second semiconductor chip,
wherein the first semiconductor chip includes a first isolator performing non-contact communication between a first potential and a second potential,
wherein the second semiconductor chip includes a second isolator performing non-contact communication between a third potential and a fourth potential,
wherein a difference between the first potential and the second potential is greater than a difference between the third potential and the fourth potential,
wherein the first isolator is configured by a first transformer or a first capacitor,
wherein the second isolator is configured by a second transformer or a second capacitor,
wherein the first transformer includes:
a first lower inductor;
a first upper inductor; and
a first insulating layer interposed between the lower inductor and the upper inductor,
wherein the second transformer includes:
a second lower inductor;
a second upper inductor; and
a second insulating layer interposed between the second lower inductor and the second upper inductor,
wherein a second distance between the second lower inductor and the second upper inductor is smaller than a first distance between the first lower inductor and the first upper inductor,
wherein the first capacitor includes:
a first lower electrode;
a first upper electrode; and
a first capacitive insulating layer interposed between the first lower electrode and the first upper electrode,
wherein the second capacitor includes:
a second lower electrode;
a second upper electrode; and
a second capacitive insulating layer interposed between the second lower electrode and the second upper electrode,
wherein a second electrode distance between the second lower electrode and the second upper electrode is smaller than a first electrode distance between the first lower electrode and the first upper electrode.

2. The electronic device according to claim 1,
wherein the first semiconductor chip includes a first multilayer wiring layer,
wherein the second semiconductor chip includes a second multilayer wiring layer,
wherein the first lower inductor is formed in the first multilayer wiring layer,
wherein the first upper inductor is formed on the first multilayer wiring layer,
wherein the second lower inductor is formed in the second multilayer wiring layer,
wherein the second upper inductor is formed on the second multilayer wiring layer,
wherein a thickness of the second multilayer wiring layer is smaller than a thickness of the first multilayer wiring layer.

3. The electronic device according to claim 1,
wherein the first semiconductor chip includes a first multilayer wiring layer,
wherein the second semiconductor chip includes a second multilayer wiring layer,
wherein the first lower electrode is formed in the first multilayer wiring layer,
wherein the first upper electrode is formed on the first multilayer wiring layer,
wherein the second lower electrode is formed in the second multilayer wiring layer,
wherein the second upper electrode is formed on the second multilayer wiring layer,
wherein a thickness of the second multilayer wiring layer is smaller than a thickness of the first multilayer wiring layer.

4. The electronic device according to claim 1,
wherein the first lower inductor and the first upper inductor are configured to be magnetically connectable to each other, and
wherein the second lower inductor and the second upper inductor are configured to be magnetically connectable to each other.

5. The electronic device according to claim 1,
wherein the first lower electrode and the first upper electrode are configured to be capacitively connectable to each other, and
wherein the second lower electrode and the second upper electrode are configured to be capacitively connectable to each other.

6. The electronic device according to claim 1, comprising:
a high-side unit; and
a low-side unit,
wherein the high-side unit includes:
a first circuit portion applying the first potential to the first lower inductor;
the first transformer; and
a second circuit portion applying the second potential to the first upper inductor,
wherein the low-side unit includes:
a third circuit portion applying the third potential to the second lower inductor;
the second transformer; and
a fourth circuit portion applying the fourth potential to the second upper inductor.

7. The electronic device according to claim 6,
wherein the first semiconductor device includes:
the first semiconductor chip; and
a high-side chip,
wherein the first circuit portion and the first transformer are formed in the first semiconductor chip,
wherein the second circuit portion is formed in the high-side chip,
wherein the second semiconductor device includes:
the second semiconductor chip; and
a low-side chip,
wherein the third circuit portion and the second transformer are formed in the second semiconductor chip, and
wherein the fourth circuit portion is formed in the low-side chip.

8. The electronic device according to claim 6,
wherein the first semiconductor device includes:
the first semiconductor chip;
a first high-side chip; and
a second high-side chip,
wherein the first circuit portion is formed in the first high-side chip,
wherein the second circuit portion is formed in the second high-side chip,
wherein the first transformer is formed in the first semiconductor chip,
wherein the second semiconductor device includes:
the second semiconductor chip;
a first low-side chip; and
a second low-side chip,
wherein the third circuit portion is formed in the first low-side chip,
wherein the fourth circuit portion is formed in the second low-side chip, and
wherein the second transformer is formed in the second semiconductor chip.

9. The electronic device according to claim 1, comprising:
a high-side unit; and
a low-side unit,
wherein the high-side unit includes:
a first circuit portion applying the first potential to the first lower electrode;
the first capacitor; and
a second circuit portion applying the second potential to the first upper electrode,
wherein the low-side unit includes:
a third circuit portion applying the third potential to the second lower electrode;
the second capacitor; and
a fourth circuit portion applying the fourth potential to the second upper electrode.

10. The electronic device according to claim 9,
wherein the first semiconductor device includes:
the first semiconductor chip; and
a high-side chip,
wherein the first circuit portion and the first capacitor are formed in the first semiconductor chip,
wherein the second circuit portion is formed in the high-side chip,
wherein the second semiconductor device includes:
the second semiconductor chip; and
a low-side chip,
wherein the third circuit portion and the second capacitor are formed in the second semiconductor chip, and
wherein the fourth circuit portion is formed in the low-side chip.

11. The electronic device according to claim 9,
wherein the first semiconductor device includes:
the first semiconductor chip;
a first high-side chip; and
a second high-side chip,
wherein the first circuit portion is formed in the first high-side chip,
wherein the second circuit portion is formed in the second high-side chip,
wherein the first capacitor is formed in the first semiconductor chip,
wherein the second semiconductor device includes:
the second semiconductor chip;
a first low-side chip; and
a second low-side chip,
wherein the third circuit portion is formed in the first low-side chip,
wherein the fourth circuit portion is formed in the second low-side chip, and
wherein the second capacitor is formed in the second semiconductor chip.

12. The electronic device according to claim 1,
wherein the electronic device is configured to control an inverter.

13. The electronic device according to claim 1,
wherein the first lower inductor includes a first lower inductor wiring,
wherein the first upper inductor includes a first upper inductor wiring,
wherein the second lower inductor includes a second lower inductor wiring,
wherein the second upper inductor includes a second upper inductor wiring,
wherein a number of turns of the second lower inductor wiring is smaller than a number of turns of the first lower inductor wiring, and
wherein a number of turns of the second upper inductor wiring is smaller than a number of turns of the first upper inductor wiring.

14. The electronic device according to claim 1,
wherein the first lower inductor includes a first lower inductor wiring,
wherein the first upper inductor includes a first upper inductor wiring,
wherein the second lower inductor includes a second lower inductor wiring,
wherein the second upper inductor includes a second upper inductor wiring,
wherein a length of the second lower inductor wiring is smaller than a length of the first lower inductor wiring, and
wherein a length of the second upper inductor wiring is smaller than a length of the first upper inductor wiring.

15. The electronic device according to claim 1,
wherein the first lower inductor includes a first lower inductor wiring,
wherein the first upper inductor includes a first upper inductor wiring,
wherein the second lower inductor includes a second lower inductor wiring,
wherein the second upper inductor includes a second upper inductor wiring,
wherein a cross-sectional area of the second lower inductor wiring in a cross section orthogonal to an extending direction of the second lower inductor wiring is smaller than a cross-sectional area of the first lower inductor wiring in a cross section orthogonal to an extending direction of the first lower inductor wiring, and
wherein a cross-sectional area of the second upper inductor wiring in a cross section orthogonal to an extending direction of the second upper inductor wiring is smaller than a cross-sectional area of the first upper inductor wiring in a cross section orthogonal to an extending direction of the first upper inductor wiring.

16. The electronic device according to claim 1,
wherein an electrode area of the second lower electrode is smaller than an electrode are of the first lower electrode, and
wherein an electrode area of the second upper electrode is smaller than an electrode are of the first upper electrode.
